(19) United States
(12) Patent Application Publication
(10) Pub. No.: US 2024/0170513 A1
(43) Pub. Date: May 23, 2024

(54) PANEL AND METHOD FOR MANUFACTURING THE SAME

(71) Applicant: CANON KABUSHIKI KAISHA, Tokyo (JP)

(72) Inventors: MASATO INOUE, Saitama (JP); YOSHITO SASAKI, Tokyo (JP); DAIKI NAKAGAWA, Kanagawa (JP)

(21) Appl. No.: 18/508,827

(22) Filed: Nov. 14, 2023

(30) Foreign Application Priority Data
Nov. 18, 2022 (JP) 2022-184870

(51) Int. Cl. H01L 27/146

(52) U.S. Cl. CPC H01L 27/1462; H01L 27/14612; H01L 27/14618; H01L 27/14685

(57) ABSTRACT

In a panel, a plurality of pixels and a circuit are connected to each other. In the panel, a cutting process with which connection between a defective pixel out of the plurality of pixels and the circuit is disconnected is performed, a protection film is formed in a cut groove of the cutting process, the protection film is formed by exposing the panel having undergone the cutting process to a gas of a protection material, and the protection film has a thickness of greater than or equal to 0.3 nm and smaller than or equal to 100 nm.

### BACKGROUND

### Technical Field

The aspect of the embodiments relates to a radiation detection apparatus and a method for manufacturing the radiation detection apparatus.

### Description of the Related Art

Today, a radiation detection apparatus in which pixels that include a conversion element converting predetermined radiations (electromagnetic radiation and particle radiation) into electrical signals and a switch element transferring the electrical signals are arranged in a matrix shape on a substrate is commercialized. The radiation detection apparatus is used in fields such as, for example, a medical radiation diagnostic system.

In the radiation detection apparatus, foreign matter may be mixed into the conversion element of a pixel or a defect may occur during the lithography in the manufacturing process of the radiation detection apparatus. In this case, as described in Japanese Patent Laid-Open No. 2002-9272 and Japanese Patent No. 4498283, a repairing process that electrically disconnect the defective pixel by radiating laser light is performed so as not to allow the defective pixel to exert an influence on normal pixels around the defective pixel.

### SUMMARY

The aspect of the embodiments provides a panel in which a plurality of pixels and a circuit are connected to each other. In the panel, a cutting process with which connection between a defective pixel out of the plurality of pixels and the circuit is disconnected is performed, a protection film is formed in a cut groove of the cutting process, the protection film is formed by exposing the panel having undergone the cutting process to a gas of a protection material, and the protection film has a thickness of greater than or equal to 0.3 nm and smaller than or equal to 100 nm.

Further features of the disclosure will become apparent from the following description of exemplary embodiments with reference to the attached drawings.

### BRIEF DESCRIPTION OF THE DRAWINGS

FIG. 1 is a plan view illustrating an appearance of a radiation detection apparatus (except for layer portions overlying pixels) according to a first embodiment.

FIGS. 2A and 2B are sectional views respectively illustrating a normal pixel and a defective pixel in the radiation detection apparatus according to the first embodiment.

FIG. 3 is a sectional view illustrating part of the radiation detection apparatus according to the first embodiment.

FIG. 4 is a sectional view illustrating a method for manufacturing a pixel part of the radiation detection apparatus according to the first embodiment.

FIG. 5 is a sectional view illustrating the method for manufacturing the pixel part of the radiation detection apparatus according to the first embodiment.

FIG. 6 is a plan view illustrating a state in which a repairing process has been performed on a defective pixel of the radiation detection apparatus according to the first embodiment.

FIGS. 7A and 7B are sectional views illustrating the individual pixels in a radiation detection apparatus according to a first variant of the radiation detection apparatus according to the first embodiment.

FIGS. 8A and 8B are sectional views illustrating the individual pixels in a radiation detection apparatus according to a second variant of the radiation detection apparatus according to the first embodiment.

FIGS. 9A and 9B are sectional views illustrating the individual pixels in a radiation detection apparatus according to another variant of the radiation detection apparatus according to the first embodiment.

FIG. 10 is a plan view illustrating a state in which the repairing process has been performed on a defective pixel of a radiation detection apparatus according to a second embodiment.

FIG. 11 is a sectional view illustrating the state in which the repairing process has been performed on the defective pixel of the radiation detection apparatus according to the second embodiment.

FIGS. 12A and 12B are sectional views respectively illustrating the normal pixel and the defective pixel in the radiation detection apparatus according to the second embodiment.

FIGS. 13A and 13B are sectional views illustrating the individual pixels in a radiation detection apparatus according to a first variant of the radiation detection apparatus according to the second embodiment.

FIGS. 14A and 14B are sectional views illustrating the individual pixels in a radiation detection apparatus according to a second variant of the radiation detection apparatus according to the second embodiment.

FIGS. 15A and 15B are sectional views illustrating the individual pixels in a radiation detection apparatus according to a third variant of the radiation detection apparatus according to the second embodiment.

FIGS. 16A and 16B are sectional views illustrating the individual pixels in a radiation detection apparatus according to another variant of the radiation detection apparatus according to the second embodiment.

FIGS. 17A and 17B are sectional views illustrating the individual pixels in a radiation detection apparatus according to another variant of the radiation detection apparatus according to the second embodiment.

FIG. 18 is a plan view illustrating a state in which the repairing process has been performed on the defective pixel of a radiation detection apparatus according to a third embodiment.

FIG. 19 is a sectional view illustrating the state in which the repairing process has been performed on the defective pixel of the radiation detection apparatus according to the third embodiment.

FIGS. 20A and 20B are sectional views respectively illustrating the normal pixel and the defective pixel in the radiation detection apparatus according to the third embodiment.

FIGS. 21A and 21B are sectional views illustrating the individual pixels in a radiation detection apparatus according to a first variant of the radiation detection apparatus according to the third embodiment.

FIGS. 22A and 22B are sectional views illustrating the individual pixels in a radiation detection apparatus according to a second variant of the radiation detection apparatus according to the third embodiment.

FIGS. 23A and 23B are sectional views illustrating the individual pixels in a radiation detection apparatus according to a third variant of the radiation detection apparatus according to the third embodiment.

FIGS. 24A and 24B are sectional views illustrating the individual pixels in a radiation detection apparatus according to another variant of the radiation detection apparatus according to the third embodiment.

FIGS. 25A and 25B are sectional views illustrating the individual pixels in a radiation detection apparatus according to another variant of the radiation detection apparatus according to the third embodiment.

FIG. 26 is a schematic view illustrating a radiation diagnostic system to which the radiation detection apparatus according to the embodiments and variants is applied.

### DESCRIPTION OF THE EMBODIMENTS

Hereinafter, various embodiments that can be applied to the disclosure will be described in detail with reference to the drawings. In the description and the drawings below, elemental members common to a plurality of the drawings are denoted by common numerals. Accordingly, common elemental members are described through cross-reference of a plurality of the drawings to omit description of elemental members denoted by common numerals as appropriate.

### First Embodiment

Initially, a first embodiment is described.

### Radiation Detection Apparatus

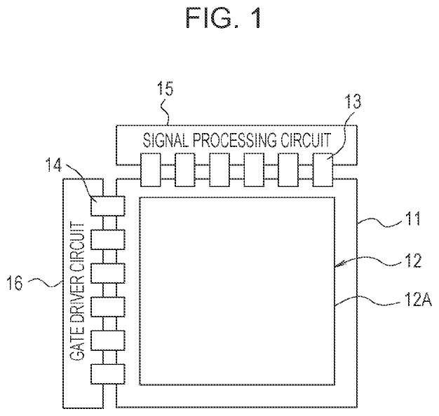

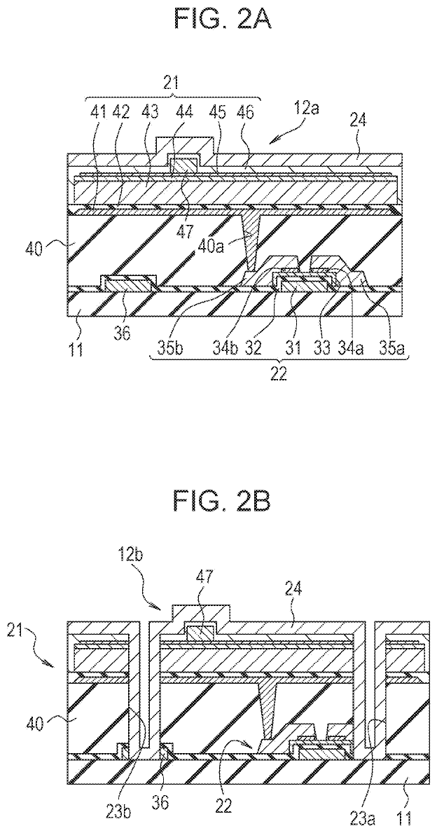

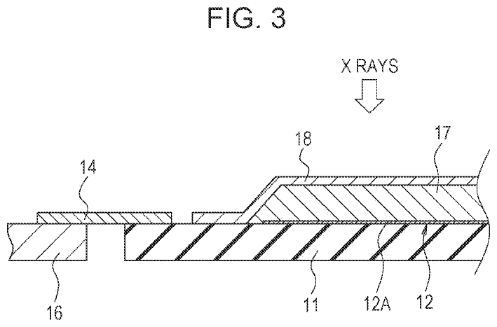

FIG. 1 is a plan view illustrating an appearance of a radiation detection apparatus (except for a layer portion overlying pixels) according to a first embodiment. FIG. 2A is a sectional view illustrating a normal pixel and FIG. 2B is a sectional view illustrating a defective pixel. FIG. 3 is a sectional view of part of FIG. 1.

As illustrated in FIG. 1, this radiation detection apparatus includes a sensor array 12 provided on an insulating substrate 11, a plurality of signal processing circuit connecting portions 13, a plurality of control circuit connecting portions 14, a signal processing circuit 15, a gate driver circuit 16, and a driver circuit (not illustrated).

The sensor array 12 is formed in a pixel region 12A positioned in a central portion of the insulating substrate 11 and configured with a plurality of pixels disposed in a matrix shape. The plurality of signal processing circuit connecting portions 13 are connecting terminals for transferring electrical signals from photoelectric conversion elements of the individual pixels to the signal processing circuit 15. The plurality of signal processing circuit connecting portions 13 are disposed on a peripheral portion along a side of the insulating substrate 11 in the transverse direction and electrically connected to the pixels of individual columns of the sensor array 12 via signal lines. The plurality of control circuit connecting portions 14 are connecting terminals for controlling the photoelectric conversion elements of the individual pixels from the gate driver circuit 16. The plurality of control circuit connecting portions 14 are disposed on a peripheral portion along a side of the insulating substrate 11 in the longitudinal direction and electrically connected to the pixels of the individual rows of the sensor array 12 through gate lines.

The signal processing circuit 15 disposed along the side of the insulating substrate 11 in the transverse direction is electrically connected to the plurality of signal processing circuit connecting portions 13 and is an electrical circuit used to read the electrical signals from the photoelectric conversion elements of the individual pixels via the signal lines and the signal processing circuit connecting portions 13. The gate driver circuit 16 disposed along the side of the insulating substrate 11 in the longitudinal direction is electrically connected to the plurality of control circuit connecting portions 14 and is an electrical circuit used to control the photoelectric conversion elements of the individual pixels via the gate lines and the control circuit connecting portions 14. The driver circuit (not illustrated) is electrically connected to the pixels of the individual columns of the sensor array 12 via bias lines.

The sensor array 12 is configured with the plurality of pixels disposed in a matrix shape. A large majority of the plurality of pixels are pixels 12a (first pixels) as illustrated in FIG. 2A that normally function. In contrast, some of the plurality of pixels may become defective pixels 12b (second pixels) as illustrated in FIG. 2B. In the pixels 12b, foreign matter has been mixed into the photoelectric conversion elements or a defect has occurred during the lithography in, for example, the manufacturing process.

The pixels 12a each include a photoelectric conversion element 21 of, for example, a metal insulator semiconductor (MIS) type and, as a switch element used to control the photoelectric conversion element 21, for example, a thin film transistor (TFT) 22. The pixels 12b each include the photoelectric conversion element 21 of, for example, the MIS type and, as the switch element used to control the photoelectric conversion element 21, for example, the TFT 22.

The TFT 22 includes a gate electrode 31, a gate insulating film 32, a channel layer 33, a pair of ohmic contact layers 34a and 34b, and a pair of ohmic electrodes 35a and 35b.

The gate insulating film 32 is formed so as to cover a surface of the gate electrode 31. The channel layer 33 is provided above the gate electrode 31 with the gate insulating film 32 interposed therebetween. The ohmic contact layers 34a and 34b are provided on the channel layer 33 such that the ohmic contact layers 34a and 34b are spaced from each other. The ohmic electrode 35a is provided on the ohmic contact layer 34a and electrically connected to the ohmic contact layer 34a. The ohmic electrode 35b is provided on the ohmic contact layer 34b and electrically connected to the ohmic contact layer 34b.

In FIGS. 2A and 2B, a signal line 36 disposed beside the TFT 22 is indicated.

The signal line 36 is provided on the insulating substrate 11 and covered by the gate insulating film 32. In the pixel 12a, the signal line 36 is electrically connected to the ohmic electrode 35a that is to serve as a source electrode. Furthermore, although it does not appear in the sectional views of FIGS. 2A and 2B, a gate line is connected to the gate electrode 31.

The photoelectric conversion element 21 is an element that converts light such as visible light or infrared light into an electrical signal. In some cases, instead of the photoelectric conversion element 21, an element that directly converts, into an electrical signal, particle radiation including α rays, β rays, and the like or electromagnetic radiation including X rays and γ rays may be used. In this case, a scintillator layer, which will be described later, is not required.

The photoelectric conversion element 21 is provided above the TFT 22 with an interlayer insulating film 40 interposed therebetween. The photoelectric conversion element 21 includes a conducting layer 41, an insulating layer 42, a photoelectric conversion layer 43, an impurity semiconductor layer 44, a conducting layer 45, and a protecting layer 46. Although FIGS. 2A and 2B exemplify the case where the photoelectric conversion element 21 covers a region above the TFT 22, the photoelectric conversion element 21 is not necessarily disposed above the TFT 22. The former photoelectric conversion element 21 can be used because the former photoelectric conversion element 21 has a large surface area and a high optical aperture ratio.

An upper surface of the interlayer insulating film 40 is planarized. A contact hole 40a that allows part of a surface of the ohmic electrode 35b that is to serve as a drain electrode of the TFT 22 to be exposed is formed in the interlayer insulating film 40. The conducting layer 41 is disposed on the interlayer insulating film 40, fills the contact hole 40a so as to be electrically connected to the ohmic electrode 35b that is to serve as the drain electrode, and functions as a lower electrode of the photoelectric conversion element 21. The insulating layer 42 is formed so as to cover the conducting layer 41. The photoelectric conversion layer 43 is disposed on the insulating layer 42 and provided so as to contain the TFT 22 disposed below the photoelectric conversion layer 43 in plan view. The impurity semiconductor layer 44 is disposed on the photoelectric conversion layer 43 that is a semiconductor layer. The conducting layer 45 is disposed on the impurity semiconductor layer 44 and functions as an upper electrode of the photoelectric conversion element 21. The protecting layer 46 is formed on the insulating layer 42 so as to cover the photoelectric conversion layer 43 that is a semiconductor layer, the impurity semiconductor layer 44, and the conducting layer 45.

In FIGS. 2A and 2B, a bias line 47 electrically connected to the conducting layer 45 on the conducting layer 45 is indicated. The bias line 47 together with the conducting layer 45 is covered with the protecting layer 46.

When the element that directly converts the radiation into the electrical signal is used instead of the photoelectric conversion element 21, a material that can convert the radiation into the electrical signal is used as the photoelectric conversion layer 43. An impurity semiconductor layer may be formed instead of the insulating layer 42. Since the conducting layer 45 does not necessarily have an optical transparency, a transparent conducting layer, which has a comparatively high resistance, is not necessarily used.

To read the electrical signal from the photoelectric conversion element 21 of the pixel 12a, the gate driver circuit 16 controls the gate line so as to set the potential of the gate electrode 31 of the TFT 22 to Hi, thereby to turn the TFT 22 on. As a result, the electrical signal from the photoelectric conversion element 21 of the pixel 12a is transferred, through the signal line 36, to the signal processing circuit 15 connected to the signal processing circuit connecting portions 13 and read. When reading of the electrical signal is completed, the gate driver circuit 16 sets the potential of the gate electrode 31 of the TFT 22 to Low, thereby to turn the TFT 22 off.

When foreign matter is mixed into the photoelectric conversion element of the pixel or a defect occurs during the lithography in the manufacturing process, the pixel in question cannot perform an original normal function, and further, the pixel in question exerts an influence such as shorting between lines on normal pixels around the pixel in question. Accordingly, a repairing process in which electrical connection of the defective pixel is disconnected by using a laser is performed. Thus, the influence on the normal pixels around the defective pixel can be suppressed, and the sensor array can be used as a confirmed item.

Cut grooves that allow parts of a surface of the insulating substrate 11 to be exposed are formed by radiating a laser light to cut portions in the pixel 12b in which the defect occurs illustrated in FIG. 2B. Cut grooves 23a and 23b are exemplified in FIG. 2B. Part of the gate electrode 31 is cut by the cut groove 23a so as to disconnect electrical connection between the pixel 12b and the gate driver circuit 16 through the gate line (not illustrated). Part of the ohmic electrode 35a that is to serve as the source electrode is cut by the cut groove 23b so as to disconnect electrical connection between the pixel 12b and the signal processing circuit 15 through the signal line 36.

As a cutting form to disconnect the electrical connection of the TFT 22 of the pixel 12b, other than the above-described cutting form, only one of the cut grooves 23a and 23b may be formed. Alternatively, a portion where the contact hole 40a for electrical connection between the photoelectric conversion element 21 and the TFT 22 is formed may be cut.

A moisture-resistant protection film 24 that covers at least surfaces (inner wall surfaces and bottom surfaces) of the cut grooves 23a and 23b is disposed in the pixel 12b. According to the present embodiment, as illustrated in FIGS. 2A and 2B, the moisture-resistant protection film 24 is disposed on the pixel 12a and the pixel 12b including the surfaces of the cut grooves 23a and 23b through, for example, the entire surface of the pixel region 12A. In the cut grooves 23a and 23b, the moisture-resistant protection film 24 is formed so as to have a recessed shape along the surfaces of the cut grooves 23a and 23b.

The moisture-resistant protection film 24 has at least a metal alkoxide and a cross link formed by cross-linking some of metal atoms of the alkoxide by oxygen. The metal alkoxide can be represented by general formula (1) below.

M(OR)ₙ (1)

Here, M can be any one selected from the group consisting of Si, Al, Ti, and Zr. R can be at least one selected from the group consisting of a methyl group (—CH₃), an ethyl group (—CH₂CH₃), a propyl group (—C₃H₇), an isopropyl group (—CH(CH₃)₂), and a butyl group (—CH₂CH₂CH₂CH₃). In the case where M is Si, Ti, or Zr, n is 4, and in the case where M is Al, n is 3. As a material using Si as M, for example, tetraethoxysilane (TEOS) or the like can be used.

As M, other than the above description, a similar moisture resistance can be expected with the atom of, for example, P, B, Hf, and Ta. Furthermore, a hydroxyl group bonded to a metal atom may be included in the moisture-resistant protection film 24. The hydroxyl group can perform hydrogen bonding to water molecules to capture the water molecules. However, since the affinity to water increases at the same time, when the moisture-resistant protection film 24 has excessive hydroxyl groups, this moisture-resistant protection film 24 cannot be used because of an increase in permeability for water molecules. Specifically, a stoichiometric ratio to the metal atom can be 2.5 times or smaller, and can be 2 times or smaller.

The moisture-resistant protection film 24 may have, instead of the metal alkoxide and the cross link, a derivative of the metal alkoxide formed by substituting the metal in the metal alkoxide by a hydrogen atom or a predetermined functional group and a cross link formed by cross-linking some of the metal atoms of the derivative with oxygen.

As the functional group, any of various alkyl groups, halogen such as fluorine (F) or the like, an amino group (—NH₂), and the like can be used. As the derivative, for example, the derivative of tetramethoxysilane (Si(OCH₃)₄) can be used. For example, trimethoxysilane (TriMS) substituted by a hydrogen atom (—H) or methyltrimethoxysilane (MTMS) substituted by a methyl group (—CH₃) can be used. Other than the above description, ODS(CH₃(CH₂)₁₇Si(OCH₃)₃), FAS17(CF₃(CF₂)₇(CH₂)₂Si(OCH₃)₃), or the like can be used. Such derivatives also react with water to undergo hydrolysis and generate a hydroxyl group in the metal atoms.

Alternatively, as the moisture-resistant protection film 24, a silica film may be formed by using silicon dioxide (silica) as the material.

It has been clarified by experiment that the moisture-resistant protection film including the metal alkoxide and the cross link of the metal alkoxide, and the like can suppress an influence of water molecules even when the thickness of the moisture-resistant protection film is reduced to the atom level. The reason for this is that, when the moisture-resistant protection film includes the metal alkoxide and the cross link of the metal alkoxide, the moisture-resistant protection film captures, consumes, or suppresses permeation of water molecules or produces compound effects of these.

When the metal alkoxide is brought into contact with water molecules, the metal alkoxide consumes the water molecules to cause hydrolysis and generates a hydroxyl group bonded to the metal atoms and alcohol molecules. Accordingly, even when water molecules permeate the moisture-resistant protection film and reach metal on the surfaces of the cut grooves, the moisture-resistant protection film can capture and consume moisture again, thereby to suppress the influence of the water molecules on the metal. Thus, according to the present embodiment, even when the moisture-resistant protection film 24 is formed to have a very small film thickness, corrosion occurring due to contact of the metal with moisture can be sufficiently suppressed.

In one embodiment, the cross link included in the moisture-resistant protection film 24 has a molar ratio of 0.02 to 1 as the stoichiometric ratio of an alkoxide atomic group to the metal atoms. The amount of the alkoxide can be controlled by adjusting activation in the reaction occurring when the metal alkoxide is cross-linked. An increase in an activation amount of the metal alkoxide reduces the amount of the alkoxide of the cross link which is a product.

A qualitative analysis of the alkoxide included in a chemical compound can be performed by using Fourier transform infrared spectroscopy (FTIR), time-of-flight secondary ion mass spectrometry (TOF-SIMS), and the like. A quantitative analysis of the alkoxide included in a chemical compound can be performed by using the FTIR, X-ray photoelectron spectroscopy (XPS), and the like. However, in one embodiment, when a quantitative analysis is performed by using the XPS, a chemical compound subjected to the quantitative analysis do not include C other than alkoxide. Furthermore, when a quantitative analysis is performed by using the FTIR, a chemical compound including only C of alkoxide is created, and first, the amount of the alkoxide is subjected to the quantitative analysis by using the XPS. Then, the quantitative analysis is performed by using the FTIR, and a calibration curve is created. The quantitative analysis is performed on the alkoxide by using this calibration curve.

When the amount of the alkoxide is excessively large with respect to the metal atoms, the amount of the cross link of the moisture-resistant protection film 24 becomes smaller. This reduces the strength of the moisture-resistant protection film 24. Furthermore, since ease of permeation of the water molecules increases due to reduction of the density of the moisture-resistant protection film 24, it cannot be used. In contrast, when the amount of the alkoxide is excessively small, the effect of capturing and consuming the water molecules reduces, and accordingly, the effect of suppressing corrosion of the metal on the surfaces of the cut grooves reduces. Thus, the amount of the alkoxide included in the cross link can be adequately adjusted.

The moisture-resistant protection film 24 is formed to have a thickness in a range greater than or equal to about 0.3 nm to smaller than or equal to about 100 nm. The shortest breadth of the cut grooves 23a and 23b illustrated in FIG. 2B is greater than or equal to about 5 μm and smaller than or equal to about 10 μm. Accordingly, when the thickness of the moisture-resistant protection film 24 is within the above-described range, the moisture-resistant protection film 24 is formed to have a recessed shape along the surfaces of the cut grooves 23a and 23b in the cut grooves 23a and 23b.

The moisture-resistant protection film 24 is disposed so as to have a uniform thickness throughout the pixel region 12A. When the thickness of the moisture-resistant protection film 24 exceeds about 100 nm, in the normal pixel 12a, fluorescence emitted in the scintillator layer disposed above the moisture-resistant protection film 24 scatters in the moisture-resistant protection film 24, and influence of the scattered light exerted on the photoelectric conversion element 21 increases. This degrades the modulation transfer function (MTF). When the thickness of the moisture-resistant protection film 24 is smaller than about 0.3 nm, the effect of suppressing permeation of the water molecules and the effect of capturing and consuming the water molecules in the surfaces of the cut grooves 23a and 23b reduce, and further, the strength of the film reduces. Thus, when the thickness of the moisture-resistant protection film 24 is in a range greater than or equal to about 0.3 nm and smaller than or equal to about 100 nm, a sufficient MTF can be ensured and corrosion of the metal in the surfaces of the cut grooves can be reliably suppressed.

As illustrated in FIG. 3, a scintillator layer 17 that covers the entire surface of the sensor array 12 is disposed above the sensor array 12. The scintillator layer 17 converts the radiation incident thereupon into light in a wavelength range that can be sensed by the photoelectric conversion element 21 such as visible light and infrared light. The scintillator layer 17 is formed to have a thickness of greater than or equal to about 300 m and smaller than or equal to about 1200 m. When the thickness of the scintillator layer 17 exceeds about 300 m, a high MTF is ensured, but detective quanta efficiency (DQE) reduces. When the thickness of the scintillator layer 17 is smaller than about 1200 m, a high DQE is ensured, but the MTF degrades. When the thickness of the scintillator layer 17 is set to greater than or equal to about 300 m and smaller than or equal to about 1200 m, a good MTF and good DQE can be ensured.

An upper moisture-resistant protection film 18 made of Al or the like is disposed above the scintillator layer 17 so as to be in contact with the scintillator layer 17. When the upper moisture-resistant protection film 18 covers a region above the scintillator layer 17, influence of the water molecules on the scintillator layer 17 is suppressed so as to suppress degradation of the scintillator layer 17.

As has been described, according to the present embodiment, in the pixel 12b where a defect occurs, the surfaces including metal exposed surfaces of the cut grooves 23a and 23b formed with the repairing process are covered with the moisture-resistant protection film 24. This moisture-resistant protection film 24 protects the metal sections from exposure to air or moisture to suppress corrosion of the metal.

In the case where iodide, for example, CsI is used as a main component of the scintillator layer 17, when the scintillator layer 17 is formed in a state in which the metal sections of the cut grooves 23a and 23b are exposed, CsI adheres to the metal sections of the cut grooves 23a and 23b. Since CsI deliquesces when the CsI is in contact with moisture, corrosion from the metal sections is accelerated by the adhering CsI. This contributes to leaks of electrical signals and breaks in lines. According to the present embodiment, the surfaces including the metal sections of the cut grooves 23a and 23b are covered with the moisture-resistant protection film 24. Thus, the metal sections are protected from exposure to air and moisture and also from adhesion of CsI. Accordingly, corrosion of the metal is suppressed.

As described above, according to the present embodiment, the moisture-resistant protection film 24 is disposed on the surfaces of the cut grooves 23a and 23b. Thus, the radiation detection apparatus of stable quality in which the pixel 12b does not exert influence on the pixel 12a around the pixel 12b is realized.

Also according to the present embodiment, the upper moisture-resistant protection film 18 that covers the scintillator layer 17 provided above the moisture-resistant protection film 24 is disposed. With the upper moisture-resistant protection film 18, degradation of the scintillator layer 17 is suppressed, and permeation of moisture to a region below the scintillator layer 17 is blocked. These effects facilitate the effect of protecting the metal sections of the cut grooves 23a and 23b by using the moisture-resistant protection film 24, thereby more reliably suppressing corrosion of the metal.

### Method for Manufacturing Radiation Detection Apparatus

Hereinafter, a method for manufacturing the radiation detection apparatus configured as described above is described.

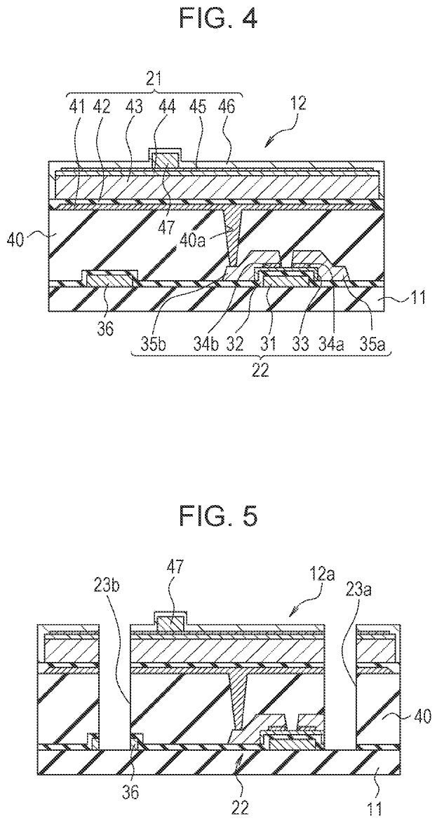

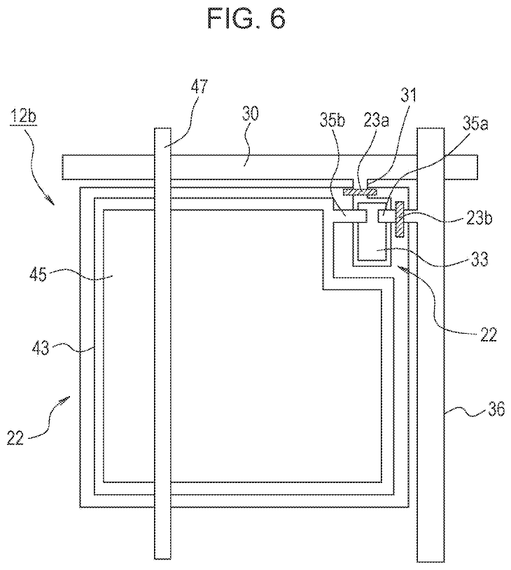

FIGS. 4 and 5 are sectional views illustrating the method for manufacturing a pixel part of the radiation detection apparatus according to the present embodiment. FIG. 6 is a plan view illustrating a state in which the repairing process has been performed on a defective pixel. FIGS. 4 and 5 exemplify the case where the photoelectric conversion element 21 covers the region above the TFT 22. FIG. 6 exemplifies the case where the photoelectric conversion element 21 does not exist above the TFT 22.

As illustrated in FIG. 4, the sensor array including the plurality of pixels 12a that each include the photoelectric conversion element 21, the TFT 22, and so forth and the plurality of pixels 12b that each include the photoelectric conversion element 21, the TFT 22, and so forth is formed on the insulating substrate 11 formed of, for example, glass.

The TFT 22 includes the gate electrode 31, the gate insulating film 32, the channel layer 33, the pair of ohmic contact layers 34a and 34b, and the pair of ohmic electrodes 35a and 35b.

The gate electrode 31, the gate line (not illustrated) connected to the gate electrode 31, and the signal line 36 are formed by, for example, depositing metal such as Cr on the insulating substrate 11 with, for example, a spattering method to a thickness of, for example, greater than or equal to about 100 nm and smaller than or equal to about 400 nm, and then performing patterning and etching the metal.

The gate insulating film 32 is formed by depositing an insulating material such as organic silicon-based siloxane, silicon nitride, or silicon oxide with, for example, a chemical-vapor deposition (CVD) method so as to cover the gate electrode 31, the signal line 36, and the like to a thickness of, for example, greater than or equal to about 150 nm and smaller than or equal to about 400 nm.

To form the channel layer 33, first, amorphous silicon is deposited on the gate insulating film 32 with, for example, the CVD method to a thickness of, for example, greater than or equal to about 200 nm and smaller than or equal to about 1000 nm. After that, the channel layer 33 is formed by, for example, performing patterning and etching the amorphous silicon to remove unnecessary portions of the amorphous silicon.

To form the pair of ohmic contact layers 34a and 34b, first, metal such as Au is deposited with, for example, the CVD method to a thickness of, for example, greater than or equal to about 10 nm and smaller than or equal to about 100 nm. To the metal, impurity such as Zn or Be is added. After that, the pair of ohmic contact layers 34a and 34b are formed by, for example, performing patterning and etching the metal to remove unnecessary portions of the metal.

The interlayer insulating film 40 is formed on the gate insulating film 32 so as to cover the TFT 22.

The interlayer insulating film 40 is formed by depositing an insulating material such as organic silicon-based siloxane, silicon nitride, or silicon oxide on the gate insulating film 32 with, for example, the CVD method or a plasma CVD method so as to cover the TFT 22 to a thickness of, for example, about 1 m. In the interlayer insulating film 40, the contact hole 40a that allows part of the surface of the ohmic electrode 35b to be exposed is formed by, for example, patterning and etching of the interlayer insulating film 40.

The photoelectric conversion element 21 includes the conducting layer 41, the insulating layer 42, the photoelectric conversion layer 43, an impurity semiconductor layer 44, the conducting layer 45, and the protecting layer 46.

The conducting layer 41 is formed by, for example, depositing metal such as Cr with the spattering method to a thickness of, for example, greater than or equal to about 150 nm and smaller than or equal to about 400 nm on the interlayer insulating film 40 so as to fill a region above the interlayer insulating film 40 and the contact hole 40a, and then performing patterning and etching the metal.

The insulating layer 42 is formed by depositing an insulating material such as organic silicon-based siloxane, silicon nitride, or silicon oxide with, for example, the CVD method so as to cover the conducting layer 41 to a thickness of, for example, greater than or equal to about 150 nm and smaller than or equal to about 400 nm.

To form the photoelectric conversion layer 43, first, amorphous silicon is deposited on the insulating layer 42 with, for example, the CVD method to a thickness of, for example, greater than or equal to about 200 nm and smaller than or equal to about 1000 nm. After that, the photoelectric conversion layer 43 is formed by, for example, performing patterning and etching the amorphous silicon to remove unnecessary portions of the amorphous silicon.

To form the impurity semiconductor layer 44, first, metal such as Au is deposited with, for example, the CVD method to a thickness of, for example, greater than or equal to about 10 nm and smaller than or equal to about 100 nm. To the metal, impurity such as Zn or Be is added. After that, the impurity semiconductor layer 44 is formed by, for example, performing patterning and etching the metal to remove unnecessary portions of the metal.

The conducting layer 45 is formed by, for example, depositing metal such as Cr on the impurity semiconductor layer 44 with, for example, the spattering method to a thickness of, for example, greater than or equal to about 100 nm and smaller than or equal to about 400 nm, and then performing patterning and etching the metal.

The bias line 47 is formed on the conducting layer 45. The bias line 47 is formed by, for example, depositing metal such as Cr with, for example, the spattering method to a thickness of, for example, greater than or equal to about 100 nm and smaller than or equal to about 400 nm, and then performing patterning and etching the metal.

The protecting layer 46 is formed. The protecting layer 46 is formed by depositing silicon nitride, silicon oxide, or the like on the insulating layer 42 with, for example, the CVD method so as to cover the photoelectric conversion layer 43, the impurity semiconductor layer 44, and the conducting layer 45 to a thickness of, for example, greater than or equal to about 200 nm and smaller than or equal to about 1000 nm.

Next, an inspection step is performed on a plurality of pixels 12 of the sensor array formed as described above. Through this inspection step, a pixel in which foreign matter has been mixed into the photoelectric conversion element 21 or a defect has occurred due to the lithography or the like is identified. Hereinafter, a pixel normal functioning of which has been verified by the inspection is referred to as a pixel 12a, and a pixel a defect of which has been found by the inspection is referred to as a pixel 12b. According to the present embodiment, the repairing process with the laser is performed on the pixel 12b.

In the repairing process, while a defective pixel is being observed with, for example, a reflection optical microscope, the laser light is radiated to cut portions of the defective pixel, thereby to disconnect electrical connection of the defective pixel with the outside. A specific example of the repairing process is illustrated in FIGS. 5 and 6. Here, the laser light is radiated to the gate electrode 31 (a gate line 30) which is an electrical connecting portion with the gate driver circuit 16 of the pixel 12b and the ohmic electrode 35a (signal line 36) that is to serve as the source electrode which is an electrical connection portion to the signal processing circuit 15 of the pixel 12b. The layers of the portions irradiated with the laser light are cut until part of the surface of the insulative substrate 11 is exposed, and thereby the cut grooves 23a and 23b are formed.

Next, the moisture-resistant protection film 24 is formed throughout the pixel region 12A including the respective surfaces of the cut grooves 23a and 23b. At this time, as illustrated in FIGS. 2A and 2B, the moisture-resistant protection film 24 is formed on the pixel 12a and the pixel 12b including the surfaces of the cut grooves 23a and 23b. In each of the pixels 12a and 12b, the moisture-resistant protection film 24 is formed so as to have a recessed shape along the surfaces of the cut grooves 23a and 23b as illustrated in FIG. 2B.

To form the moisture-resistant protection film 24, the metal alkoxide, the derivative of the metal alkoxide, or the silicon dioxide (silica) is used as the material.

The moisture-resistant protection film 24 can be formed with methods such as the spattering method, the CVD method, and the plasma CVD method. Other than these, as the methods for forming the moisture-resistant protection film 24, for example, there are the following methods.

When the metal alkoxide or the derivative of the metal alkoxide is used as the material of the moisture-resistant protection film 24, the metal alkoxide or the derivative of the metal alkoxide is brought into contact with the sensor array to cause a reaction. This reaction can be activated and promoted by heat, plasma, chemical reaction, or the like.

According to the present embodiment, as the material of the moisture-resistant protection film 24, TriMS, which is a derivative of the metal alkoxide, can be used particularly because the TriMS is cheap and has good versatility. In a film forming apparatus for forming the TriMS, a container in which the material of the moisture-resistant protection film (TriMS) is contained and a container in which the sensor array for which the moisture-resistant protection film is formed is set are connected to each other. When the container in which the sensor array is set is evacuated, the moisture-resistant protection film material vaporized at room temperature is caused to flow into the container in which the sensor array is set by using the difference in atmospheric pressure, and thereby the moisture-resistant protection film 24 is formed on the sensor array. According to a film forming method with this film forming apparatus, the film can be formed with simple equipment at room temperature. Thus, work efficiency is good and the cost required for the film forming is reduced compared to the spattering method, the CVD method, and the plasma CVD method.

Furthermore, when TEOS being the metal alkoxide is used as the material of the moisture-resistant protection film 24, there is a sol-gel method as one of the methods for forming the moisture-resistant protection film 24. First, a mixed solution of TEOS and isopropanol is added to a hydrochloric acid aqueous solution, and the resultant solution is heated at about 60° C. to create a sol solution A. Next, an acetic acid aqueous solution is added to a mixed solution of methyltriethoxysilane (MTES) and isopropanol, and a sol solution B is created at about 60° C. The sol solution A and the sol solution B that have been created are mixed with each other to create a coating solution. This coating solution remaining in a liquid without being gasified is used for the film forming with a method such as a nozzle flow method, a spraying method, or a spinning method and subjected to a heating process at about 600° C. Thus, the moisture-resistant protection film 24 is formed. According to this film forming method, the moisture-resistant protection film material is used without being gasified. Thus, the film can be formed with simple equipment.

When the silicon dioxide (silica) is used as the material of the moisture-resistant protection film 24, for example, tetraalkyl orthosilicate, an organic solvent such as alcohol, and water are admixed and reacted to create a solution. This solution is applied to the sensor array with a spin coating method, a blade coating method, a roll coating method, a dipping method, spray coating method, or the like to form the moisture-resistant protection film 24. Other than the above-described methods of applying, various types of method including a transferring method, a screen printing method, and an ejecting method such as an ink-jet printing method may be used to form the moisture-resistant protection film 24. The film thickness of the moisture-resistant protection film 24 to be formed is controlled by the method of forming or viscosity. For example, when the spin coating method is used, the insulative substrate on which the sensor array being an object of forming the moisture-resistant protection film 24 is formed is rotated at greater than or equal to about 1000 rpm and smaller than or equal to about 5000 rpm for about 60 seconds. In this case, the film can be formed to a thickness of greater than or equal to about 60 nm and smaller than or equal to 150 nm. After the film forming step, a drying step through which moisture in the film is reduced, an additional hydrolysis step for the film, and a heating step that removes moisture in the film and increases strength are performed to obtain the objective moisture-resistant protection film 24.

Next, similarly to FIG. 3, the scintillator layer 17 that covers an upper portion of the sensor array 12 is formed.

As the material of the scintillator layer 17, CsI (cesium iodide) is used as a main agent and TlI (thallium iodide) is used as an activator. CsI and TlI are vaporized in a predetermined vacuum at high temperature with a vapor deposition method to deposit the CsI and TlI on the sensor array 12 to a thickness of greater than or equal to about 300 m and smaller than or equal to about 1200 m, thereby to form the scintillator layer 17.

Next, similarly to FIG. 3, Al or the like is deposited with the spattering method so as to cover the region above the scintillator layer 17 to form the upper moisture-resistant protection film 18.

After that, the plurality of signal processing circuit connecting portions 13 and the plurality of control circuit connecting portions 14 are formed so as to be electrically connected to the lines of the sensor array 12, the signal processing circuit 15 is connected to the signal processing circuit connecting portions 13, and the gate driver circuit 16 is connected to the control circuit connecting portions 14.

### Variants of First Embodiment

Hereinafter, variants of the first embodiment are described. Although these variants have a similar configuration as that of the radiation detection apparatus according to the first embodiment, the variants are different from the first embodiment in that a forming manner of the moisture-resistant protection film is different from that of the first embodiment.

### First Variant

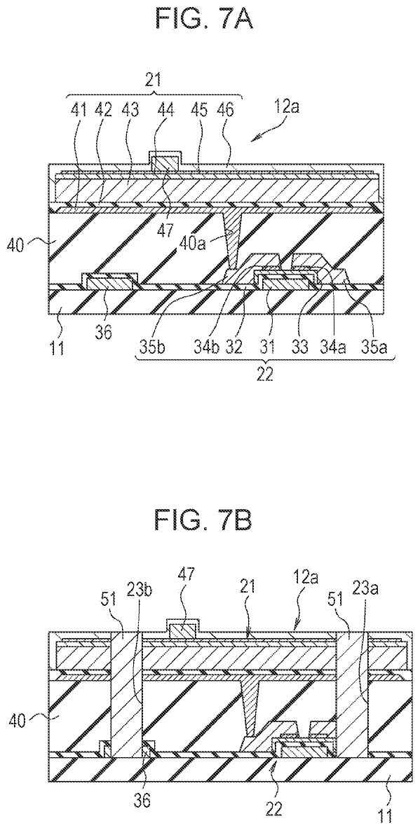

FIGS. 7A and 7B are sectional views illustrating the individual pixels in the radiation detection apparatus according to a first variant, respectively illustrating the normal pixel and the defective pixel.

According to the first variant, the normal pixel 12a is formed similarly to that illustrated in FIG. 2A of the first embodiment. In the pixel 12b in which a defect has occurred, the cut grooves 23a and 23b are formed as those illustrated in FIG. 2B of the first embodiment.

In the radiation detection apparatus according to the first variant, a moisture-resistant protection film 51 is disposed only in the cut grooves 23a and 23b so as to fill the cut grooves 23a and 23b in the pixel 12b. The moisture-resistant protection film 51 is not formed in a region of the pixel 12a or a region of the pixel 12b other than the cut grooves 23a and 23b. Similarly to the first embodiment, the moisture-resistant protection film 51 has the metal alkoxide and the cross link of the metal alkoxide, the derivative of the metal alkoxide and the cross link of the derivative of the metal alkoxide, or the silicon dioxide (silica).

To form the moisture-resistant protection film 51, a so-called ejecting method in which the material is sprayed with an ejection head having a very small ejection orifice can be applied. According to the first variant, with the ejecting method, the moisture-resistant protection film material can be thickly supplied only to the inside of the cut grooves 23a and 23b so as to fill the cut grooves 23a and 23b in a short time.

After the moisture-resistant protection film 51 has been formed, similarly to the first embodiment, for example, the scintillator layer 17 that covers the entire surface the sensor array 12 is formed, the upper moisture-resistant protection film 18 made of Al or the like that covers the scintillator layer 17 is formed, and connection of the signal processing circuit connecting portions 13 and connection of the control circuit connecting portions 14 are performed.

According to the first variant, in the pixel 12b in which a defect has occurred, the surfaces including the metal sections of the cut grooves 23a and 23b formed with the repairing process are covered with the moisture-resistant protection film 51. Since the moisture-resistant protection film 51 is not formed in a region other than the cut grooves 23a and 23b, there is no concern for degradation of the MTF due to the formation of the moisture-resistant protection film 51. Since the moisture-resistant protection film 51 is formed only in the cut grooves 23a and 23b which are portions that are to be moisture resistant to a thickness with which the cut grooves 23a and 23b are filled, no gap exists in the cut grooves 23a and 23b. Accordingly, the metal sections of the cut grooves are reliably protected from exposure to air or water by using the thick moisture-resistant protection film 51 having no gap while a high MTF is ensured. Thus, corrosion of the metal is suppressed as much as possible, and the radiation detection apparatus of stable quality in which the pixel 12b does not exert influence on the pixel 12a around the pixel 12b is realized.

### Second Variant

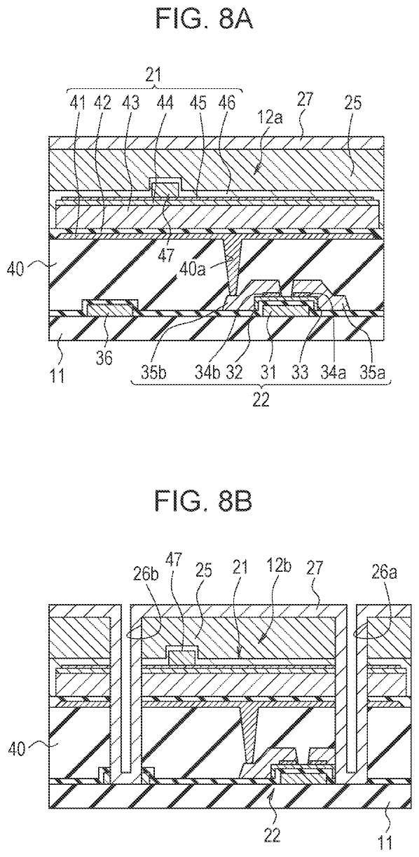

FIGS. 8A and 8B are sectional views illustrating the individual pixels in the radiation detection apparatus according to a second variant, respectively illustrating the normal pixel and the defective pixel.

In the radiation detection apparatus according to the second variant, a planarization layer 25 is disposed on the protecting layer 46 in the normal pixels 12a and the pixels 12b in which a defect has occurred so as to cover the pixel region 12A. The planarization layer 25 is formed of polyimide (PI), perfluoroalkoxy alkane (PFA), or the like. An upper surface of the planarization layer 25 is formed as a planarized surface.

To form the planarization layer 25, for example, PI used as the material is applied to an entire surface on the protecting layer 46 with a spinner. The planarization layer may be formed by using screen printing or a roll coater instead of use of the spinner.

After pixel inspection has been performed and the pixel 12b in which a defect had occurred has been identified, the laser light is radiated to the planarization layer 25 and the layers below the planarization layer 25 in the pixel 12b to form cut grooves 26a and 26b that allow part of the surface of the insulating substrate 11 to be exposed. With the cut grooves 26a and 26b, the electrical connection of the TFT 22 of the pixel 12b to the signal processing circuit 15 and the gate driver circuit 16 is disconnected. As illustrated in FIG. 8B, the gate electrode 31 is cut by the cut groove 26a so as to disconnect the electrical connection between the pixel 12b and the gate driver circuit 16 through the gate line (not illustrated). The ohmic electrode 35a that is to serve as the source electrode is cut by the cut groove 26b so as to disconnect the electrical connection between the pixel 12b and the signal processing circuit 15 through the signal line 36.

A moisture-resistant protection film 27 that covers at least surfaces of the cut grooves 26a and 26b is disposed in the pixel 12b. The moisture-resistant protection film 27 is disposed on the pixel 12a and the pixel 12b including the surfaces of the cut grooves 26a and 26b through, for example, the entire surface of the pixel region 12A. In the cut grooves 26a and 26b, the moisture-resistant protection film 27 is formed so as to have a recessed shape along the surfaces of the cut grooves 26a and 26b to a thickness of, for example, greater than or equal to about 0.3 nm and smaller than or equal to about 100 nm. Similarly to the first embodiment, the moisture-resistant protection film 27 has metal alkoxide and the cross link of the metal alkoxide, the derivative of the metal alkoxide and the cross link of the derivative of the metal alkoxide, or the silicon dioxide (silica) and is formed with the film forming method similar to that of the first embodiment.

After the moisture-resistant protection film 27 has been formed, similarly to the first embodiment, for example, the scintillator layer 17 that covers the entire surface of the sensor array 12 is formed, the upper moisture-resistant protection film 18 made of Al or the like that covers the scintillator layer 17 is formed, and connection of the signal processing circuit connecting portions 13 and connection of the control circuit connecting portions 14 are performed. When the upper surface of the planarization layer 25 on which the scintillator layer 17 is formed is formed as a planarized surface, the occurrences of irregularities of a vapor deposition surface are suppressed, and the scintillator layer 17 exhibiting a good crystallinity for CsI or the like can be obtained.

According to the second variant, in the pixel 12b in which a defect has occurred, the surfaces including the metal sections of the cut grooves 26a and 26b formed with the repairing process are covered with the moisture-resistant protection film 27. Thus, the radiation detection apparatus of stable quality in which the pixel 12b does not exert influence on the pixel 12a around the pixel 12b is realized.

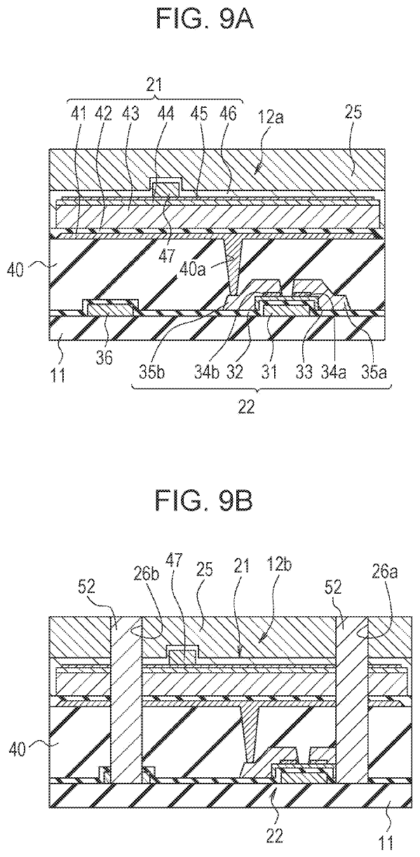

The first variant can be further applied to the second variant. FIGS. 9A and 9B are sectional views illustrating a defective pixel in the radiation detection apparatus in this case.

In the second variant, the cut grooves 26a and 26b are formed with the repairing process in a state in which the planarization layer 25 has been formed, and, similarly to the above-described first variant, a moisture-resistant protection film 52 is formed so as to fill only the inside of the cut grooves 26a and 26b. The moisture-resistant protection film 52 is not formed in a region other than the cut grooves 26a and 26b. To form the moisture-resistant protection film 52, similarly to the first variant, the moisture-resistant protection film material is supplied with, for example, the ejecting method only to the cut grooves 26a and 26b so as to fill the inside of the cut grooves 26a and 26b.

### Second Embodiment

Hereinafter, a second embodiment is described. Although the present embodiment has a similar configuration as that of the radiation detection apparatus according to the first embodiment, the second embodiment is different from the first embodiment in that a forming manner of the cut grooves in the repairing process is different from that of the first embodiment.

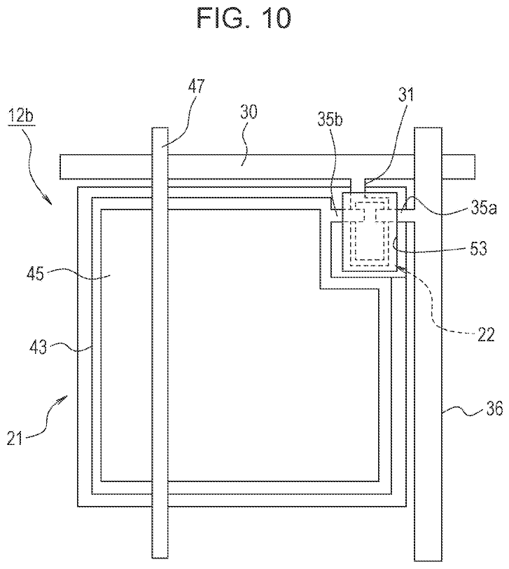

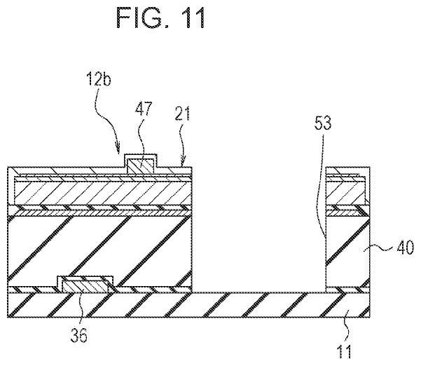

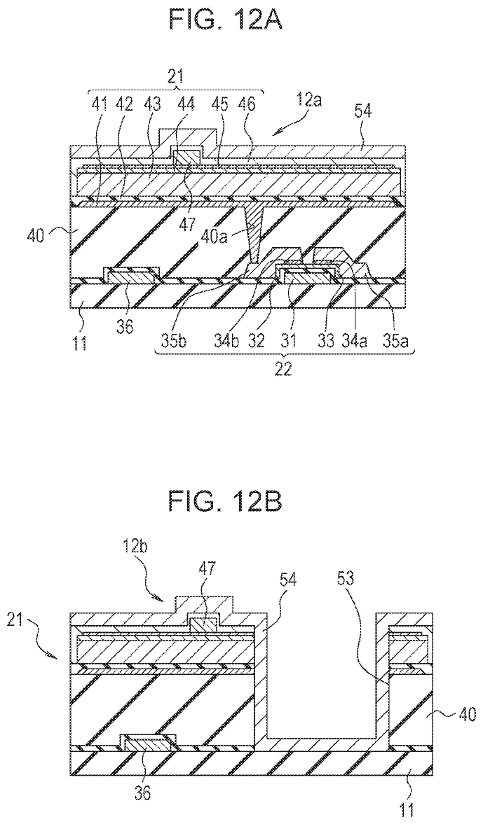

FIG. 10 is a plan view illustrating a state in which the repairing process has been performed on a defective pixel of the radiation detection apparatus according to the second embodiment. FIG. 11 is a sectional view illustrating the state in which the repairing process has been performed on the defective pixel. FIGS. 12A and 12B are sectional views illustrating the individual pixels in the radiation detection apparatus according to the second embodiment, respectively illustrating the normal pixel and the defective pixel. FIG. 10 exemplifies the case where the photoelectric conversion element 21 does not exist above the TFT 22. FIGS. 11 and 12A exemplify the case where the photoelectric conversion element 21 covers the region above the TFT 22.

In the radiation detection apparatus according to the present embodiment, a cut groove 53 that allows part of the surface of the insulating substrate 11 to be exposed is formed in the pixel 12b in which a defect has occurred, and the electrical connection of the pixel 12b with the signal processing circuit 15 and the gate driver circuit 16 is disconnected. As illustrated in FIGS. 10 and 11, the cut groove 53 is formed in a portion of the pixel 12a corresponding to a placement position of the TFT 22. That is, the cut groove 53 is a groove formed in a portion where the TFT 22 of the pixel 12b has been removed by radiation of the laser light in the repairing process, the portion where the TFT 22 existed. Referring to FIG. 10, a portion removed with the repairing process is indicated by a broken line. When the TFT 22 of the pixel 12b is removed, the electrical connection of the pixel 12b is reliably disconnected.

A moisture-resistant protection film 54 that covers at least a surface of the cut groove 53 is disposed in the pixel 12b. According to the present embodiment, as illustrated in FIGS. 12A and 12B, the moisture-resistant protection film 54 is disposed on the pixel 12a and the pixel 12b including the surface of the cut groove 53 through, for example, the entire surface of the pixel region 12A. In the cut groove 53, the moisture-resistant protection film 54 is formed so as to have a recessed shape along the surface of the cut groove 53 to a thickness of, for example, greater than or equal to about 0.3 nm and smaller than or equal to about 100 nm similarly to the first embodiment. Similarly to the first embodiment, the moisture-resistant protection film 54 has the metal alkoxide and the cross link of the metal alkoxide, the derivative of the metal alkoxide and the cross link of the derivative of the metal alkoxide, or the silicon dioxide (silica) and is formed with the film forming method similar to that of the first embodiment.

After the moisture-resistant protection film 54 has been formed, similarly to the first embodiment, for example, the scintillator layer 17 that covers the entire surface of the sensor array 12 is formed, the upper moisture-resistant protection film 18 made of Al or the like that covers the scintillator layer 17 is formed, and connection of the signal processing circuit connecting portions 13 and connection of the control circuit connecting portions 14 are performed.

According to the present embodiment, in the pixel 12b in which a defect has occurred, the surface including the metal section of the cut groove 53 formed by removing the TFT 22 with the repairing process is covered with the moisture-resistant protection film 54 having a small thickness. Thus, while the MTF is sufficiently ensured, the metal section of the surface of the cut groove 53 is protected from exposure to air or water, corrosion of the metal is suppressed, and the radiation detection apparatus of stable quality in which the pixel 12b does not exert influence on the pixel 12a around the pixel 12b is realized.

### Variants of Second Embodiment

Hereinafter, variants of the second embodiment are described. Although these variants have a similar configuration as that of the radiation detection apparatus according to the second embodiment, the variants are different from the second embodiment in that a forming manner of the moisture-resistant protection film is different from that of the second embodiment.

### First Variant

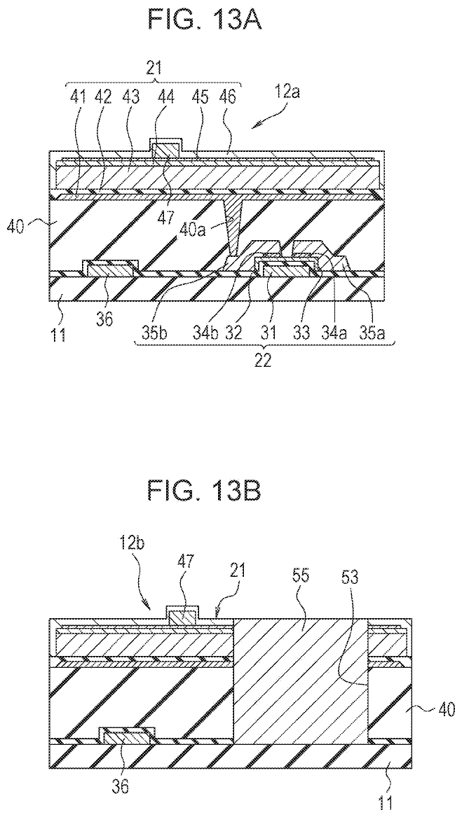

FIGS. 13A and 13B are sectional views illustrating the individual pixels in the radiation detection apparatus according to a first variant, respectively illustrating the normal pixel and the defective pixel.

According to the first variant, the normal pixel 12a is formed similarly to that illustrated in FIG. 12A of the second embodiment. Similarly to that illustrated in FIG. 12B of the second embodiment, in the pixel 12b in which a defect has occurred, the TFT 22 is removed by radiation of the laser beam and the cut groove 53 is formed.

In the radiation detection apparatus according to the first variant, a moisture-resistant protection film 55 is disposed only in the cut groove 53 so as to fill the cut groove 53 in the pixel 12b. The moisture-resistant protection film 55 is not formed in the pixel 12a or a region of the pixel 12b other than the cut groove 53. Similarly to the second embodiment, the moisture-resistant protection film 55 has the metal alkoxide and the cross link of the metal alkoxide, the derivative of the metal alkoxide and the cross link of the derivative of the metal alkoxide, or the silicon dioxide (silica).

To form the moisture-resistant protection film 55, the ejecting method in which the material is sprayed with the ejection head having a very small ejection orifice can be applied. According to the first variant, with the ejecting method, the moisture-resistant protection film material can be thickly supplied only to the inside of the cut groove 53 so as to fill the cut groove 53 in a short time.

After the moisture-resistant protection film 55 has been formed, similarly to the second embodiment, for example, the scintillator layer 17 that covers the entire surface of the sensor array 12 is formed, the upper moisture-resistant protection film 18 made of Al or the like that covers the scintillator layer 17 is formed, and connection of the signal processing circuit connecting portions 13 and connection of the control circuit connecting portions 14 are performed.

According to the first variant, the surface including the metal section of the cut groove 53 formed with the repairing process is covered with the moisture-resistant protection film 55 in the pixel 12b in which a defect has occurred. Since the moisture-resistant protection film 55 is not formed in a region other than the cut groove 53, there is no concern for degradation of the MTF due to the formation of the moisture-resistant protection film 55. Since the moisture-resistant protection film 55 is formed only in the cut groove 53 which is a portion that is to be moisture resistant to a thickness with which the cut groove 53 is filled, no gap exists in the cut groove 53. Accordingly, the metal section in the surface of the cut groove 53 is reliably protected from exposure to air or water by using the thick moisture-resistant protection film 55 having no gap while a high MTF is ensured. Thus, corrosion of the metal is suppressed as much as possible, and the radiation detection apparatus of stable quality in which the pixel 12b does not exert influence on the pixel 12a around the pixel 12b is realized.

### Second Variant

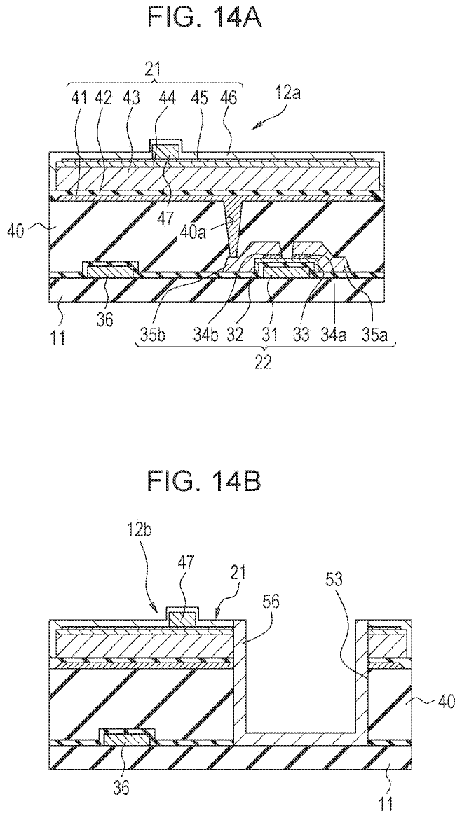

FIGS. 14A and 14B are sectional views illustrating the individual pixels in the radiation detection apparatus according to a second variant, respectively illustrating the normal pixel and the defective pixel.

According to the second variant, the normal pixel 12a is formed similarly to that illustrated in FIG. 12A of the second embodiment. Similarly to that illustrated in FIG. 12B of the second embodiment, in the pixel 12b in which a defect has occurred, the TFT 22 is removed by radiation of the laser beam and the cut groove 53 is formed.

In the radiation detection apparatus according to the second variant, a moisture-resistant protection film 56 is disposed only in the cut groove 53 so as to have a recessed shape along the surface of the cut groove 53 in the pixel 12b. Similarly to the second embodiment, the moisture-resistant protection film 56 has the metal alkoxide and the cross link of the metal alkoxide, the derivative of the metal alkoxide and the cross link of the derivative of the metal alkoxide, or the silicon dioxide (silica) and is formed to have a thickness of, for example, about 0.3 nm to about 100 nm.

To form the moisture-resistant protection film 56, first, a mask that has an opening which allows only the cut groove 53 of the pixel 12b to be exposed and covers portions of the pixel 12b other than the cut groove 53 and a region on the pixel 12a is formed in the sensor array. The cut groove 53 is a groove formed by removing the TFT 22 of the pixel 12b, and the area and both the widths of the cut groove 53 are comparatively large. Accordingly, a mask having the opening that is aligned with the cut groove 53 so as to expose only the cut groove 53 can be easily formed. In one embodiment, the opening is exactly aligned with the cut groove 53. The film forming method similar to that of the second embodiment is executed for the insulating substrate 11 provided with this mask on the sensor array 12 to deposit the moisture-resistant protection film material on the entire surface of the mask including the surface of the cut groove 53 of the pixel 12b exposed from the opening. Then, the mask is removed. As a result of the above-described operation, the moisture-resistant protection film 56 is formed only in the cut groove 53 so as to have a recessed shape along the surface of the cut groove 53 to a thickness of, for example, greater than or equal to about 0.3 nm and smaller than or equal to about 100 nm similarly to the first embodiment.

After the moisture-resistant protection film 56 has been formed, similarly to the second embodiment, for example, the scintillator layer 17 that covers the entire surface of the sensor array 12 is formed, the upper moisture-resistant protection film 18 made of Al or the like that covers the scintillator layer 17 is formed, and connection of the signal processing circuit connecting portions 13 and connection of the control circuit connecting portions 14 are performed.

According to the second variant, the surface including the metal section of the cut groove 53 formed with the repairing process is covered with the moisture-resistant protection film 56 in the pixel 12b in which a defect has occurred. Since the moisture-resistant protection film 56 is not formed in the region other than the cut groove 53, there is no concern for degradation of the MTF due to the formation of the moisture-resistant protection film 56. With the moisture-resistant protection film 56, while a high MTF is ensured, the metal section of the surface of the cut groove 53 is protected from exposure to air or water, corrosion of the metal is suppressed, and the radiation detection apparatus of stable quality in which the pixel 12b does not exert influence on the pixel 12a around the pixel 12b is realized.

### Third Variant

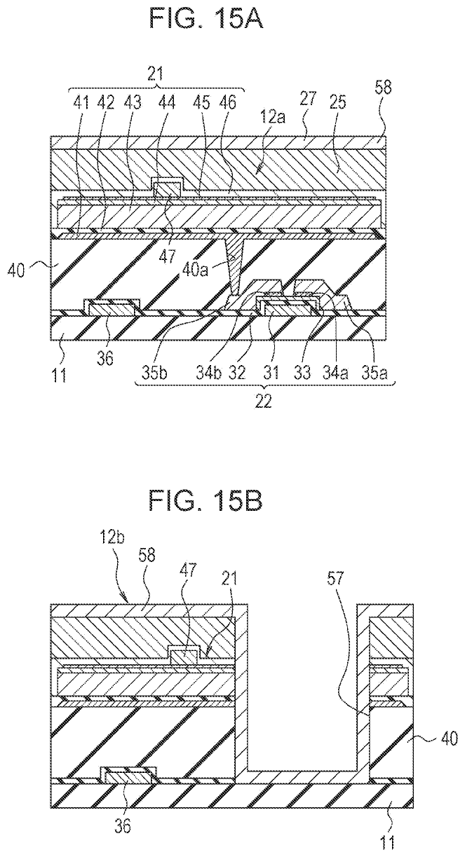

FIGS. 15A and 15B are sectional views illustrating the individual pixels in the radiation detection apparatus according to a third variant, respectively illustrating the normal pixel and the defective pixel.

In the radiation detection apparatus according to the third variant, similarly to the second variant of the first embodiment, the planarization layer 25 is disposed on the protecting layer 46 in the normal pixels 12a and the pixels 12b in which a defect has occurred so as to cover the pixel region 12A.

The TFT 22 of the pixel 12b is removed by radiation of the laser light in a state in which the planarization layer 25 has been formed. At this time, a cut groove 57 that allows part of the surface of the insulating substrate 11 to be exposed is formed in a portion of the pixel 12b where the TFT 22 existed. With the cut groove 57, the electrical connection of the pixel 12b to the signal processing circuit 15 and the gate driver circuit 16 is disconnected.

A moisture-resistant protection film 58 is disposed on the pixel 12a and the pixel 12b including the surface of the cut groove 57 through, for example, the entire surface of the pixel region 12A. In the cut groove 57, the moisture-resistant protection film 58 is formed so as to have a recessed shape along the surface of the cut groove 57 to a thickness of, for example, greater than or equal to about 0.3 nm and smaller than or equal to about 100 nm with the film forming method similar to that of the second embodiment.

After the moisture-resistant protection film 58 has been formed, for example, the scintillator layer 17 that covers the entire surface of the sensor array 12 is formed, the upper moisture-resistant protection film 18 made of Al or the like that covers the scintillator layer 17 is formed, and connection of the signal processing circuit connecting portions 13 and connection of the control circuit connecting portions 14 are performed. When the upper surface of the planarization layer 25 on which the scintillator layer 17 is formed is formed as a planarized surface, the occurrences of irregularities of the vapor deposition surface are suppressed, and the scintillator layer 17 exhibiting a good crystallinity for CsI or the like can be obtained.

According to the present embodiment, in the pixel 12b in which a defect has occurred, the surface including the metal section of the cut groove 57 formed by removing the TFT 22 with the repairing process is covered with the moisture-resistant protection film 58 having a small thickness. Thus, while the MTF is sufficiently ensured, the metal section of the surface of the cut groove 57 is protected from exposure to air or water, corrosion of the metal is suppressed, and the radiation detection apparatus of stable quality in which the pixel 12b does not exert influence on the pixel 12a around the pixel 12b is realized.

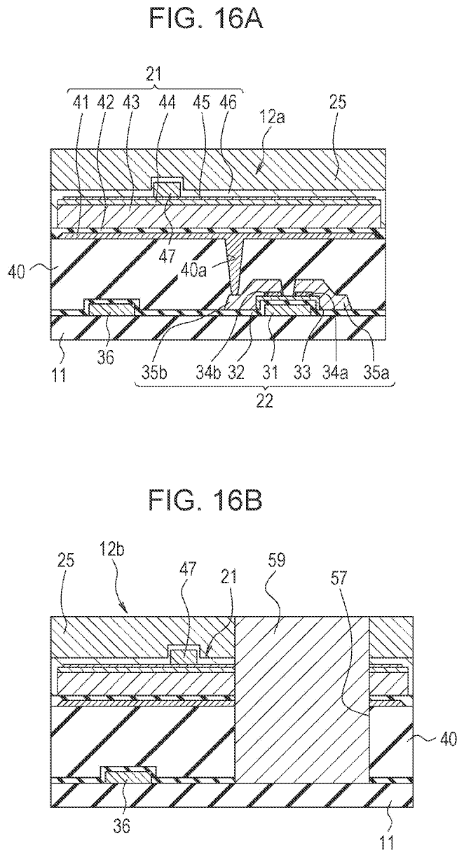

The first variant can be further applied to the third variant. FIGS. 16A and 16B are sectional views illustrating a defective pixel in the radiation detection apparatus in this case.

In the third variant, the cut groove 57 is formed with the repairing process in a state in which the planarization layer 25 has been formed, and, similarly to the above-described first variant, a moisture-resistant protection film 59 is formed so as to fill only the inside of the cut groove 57. The moisture-resistant protection film 59 is not formed in a region other than the cut groove 57. To form the moisture-resistant protection film 59, similarly to the first variant, the moisture-resistant protection film material is supplied with, for example, the ejecting method only to the cut groove 57 so as to fill the inside of the cut groove 57.

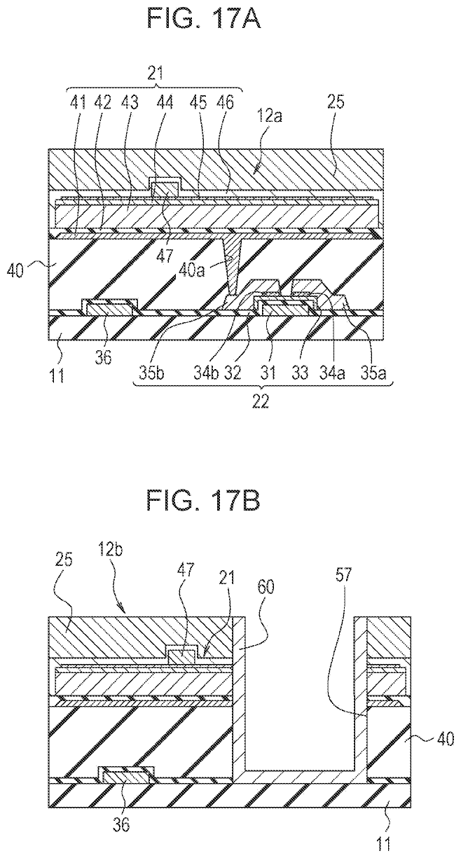

In addition, the second variant can be further applied to the third variant. FIGS. 17A and 17B are sectional views illustrating a defective pixel in the radiation detection apparatus in this case.

In the third variant, the cut groove 57 is formed with the repairing process in a state in which the planarization layer 25 has been formed, and, similarly to the above-described second variant, a moisture-resistant protection film 60 is formed only in the cut groove 57 so as to have a recessed shape along the surface of the cut groove 57 to a thickness of, for example, greater than or equal to about 0.3 nm and smaller than or equal to about 100 nm. The moisture-resistant protection film 60 is not formed in a region other than the cut groove 57. To form the moisture-resistant protection film 60, similarly to the second variant, a mask having an opening is formed on the sensor array 12, the film is formed, and the mask is removed.

### Third Embodiment

Hereinafter, a third embodiment is described. Although the present embodiment has a similar configuration as that of the radiation detection apparatus according to the first and second embodiments, the third embodiment is different from the first and second embodiments in that a forming manner of the cut grooves in the repairing process is different from that of the first and second embodiments.

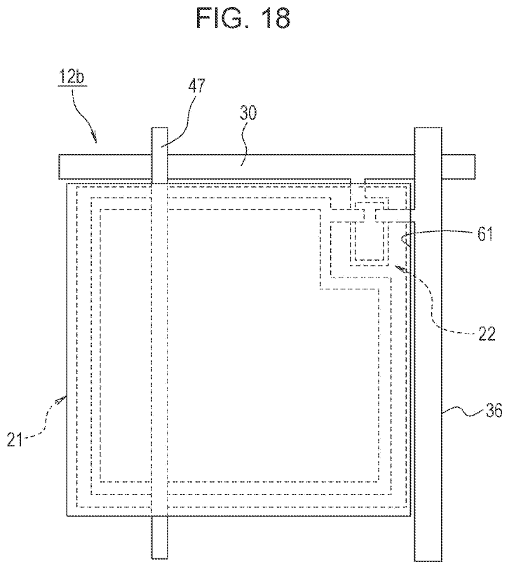

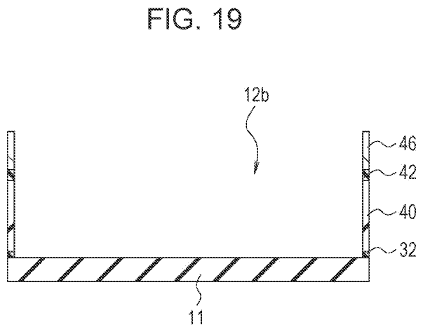

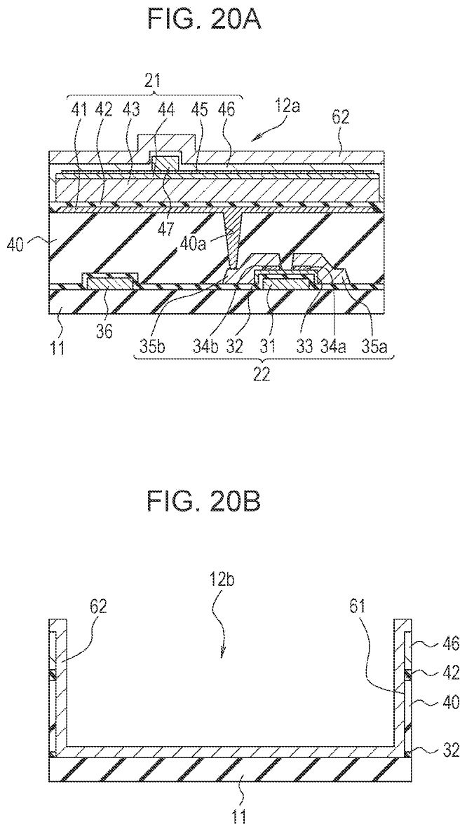

FIG. 18 is a plan view illustrating a state in which the repairing process has been performed on the defective pixel of a radiation detection apparatus according to a third embodiment. FIG. 19 is a sectional view illustrating the state in which the repairing process has been performed on the defective pixel. FIGS. 20A and 20B are sectional views illustrating the individual pixels in the radiation detection apparatus according to the second embodiment, respectively illustrating the normal pixel and the defective pixel. FIG. 18 exemplifies the case where the photoelectric conversion element 21 does not exist above the TFT 22. FIGS. 19 and 20A exemplify the case where the photoelectric conversion element 21 covers the region above the TFT 22.

In the radiation detection apparatus according to the present embodiment, a cut groove 61 that allows part of the surface of the insulating substrate 11 to be exposed is formed in the pixel 12b in which a defect has occurred, and the electrical connection of the pixel 12b with the signal processing circuit 15 and the gate driver circuit 16 is disconnected. As illustrated in FIGS. 18 and 19, the cut groove 61 is formed in a portion corresponding to placement positions of the photoelectric conversion element 21 and the TFT 22 of the pixel 12a. That is, the cut groove 61 is a groove formed through a substantially entire region of the pixel 12b where the photoelectric conversion element 21 and the TFT 22 of the pixel 12b are removed by radiation of the laser light in the repairing process. Referring to FIG. 18, portions removed with the repairing process are indicated by broken lines. When the photoelectric conversion element 21 and the TFT 22 of the pixel 12b are removed, the electrical connection of the pixel 12b is reliably disconnected.

A moisture-resistant protection film 62 that covers a surface of the cut groove 61 is disposed in the pixel 12b. According to the present embodiment, as illustrated in FIGS. 20A and 20B, the moisture-resistant protection film 62 is disposed on the pixel 12a and the surfaces of the cut groove 61 of the pixel 12b through, for example, the entire surface of the pixel region 12A. In the cut groove 61, the moisture-resistant protection film 62 is formed so as to have a recessed shape along the surface of the cut groove 61 to a thickness of, for example, greater than or equal to about 0.3 nm and smaller than or equal to about 100 nm similarly to the first and second embodiments. Similarly to the first and second embodiments, the moisture-resistant protection film 62 has metal alkoxide and the cross link of the metal alkoxide, the derivative of the metal alkoxide and the cross link of the derivative of the metal alkoxide, or the silicon dioxide (silica) and is formed with the film forming method similar to that of the first and second embodiment.

After the moisture-resistant protection film 62 has been formed, similarly to the first and second embodiments, for example, the scintillator layer 17 that covers the entire surface of the sensor array 12 is formed, the upper moisture-resistant protection film 18 made of Al or the like that covers the scintillator layer 17 is formed, and connection of the signal processing circuit connecting portions 13 and connection of the control circuit connecting portions 14 are performed.

According to the present embodiment, in the pixel 12b in which a defect has occurred, the surface including the metal section of the cut groove 61 formed by removing a substantially entire part of the pixel 12b with the repairing process is covered with the moisture-resistant protection film 62 having a small thickness. Thus, while the MTF is sufficiently ensured, the metal section of the surface of the cut groove 61 is protected from exposure to air or water, corrosion of the metal is suppressed, and the radiation detection apparatus of stable quality in which the pixel 12b does not exert influence on the pixel 12a around the pixel 12b is realized.

### Variants of Third Embodiment

Hereinafter, variants of the third embodiment are described. Although these variants have a similar configuration as that of the radiation detection apparatus according to the third embodiment, the variants are different from the third embodiment in that a forming manner of the moisture-resistant protection film is different from that of the third embodiment.

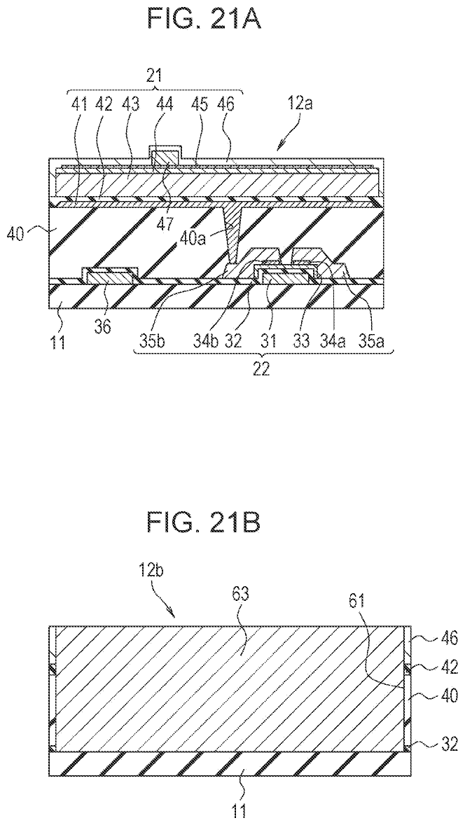

FIGS. 21A and 21B are sectional views illustrating the individual pixels in the radiation detection apparatus according to a first variant, respectively illustrating the normal pixel and the defective pixel.

According to the first variant, the normal pixel 12a is formed similarly to that illustrated in FIG. 20A of the third embodiment. Similarly to that illustrated in FIG. 20B of the third embodiment, in the pixel 12b in which a defect has occurred, the photoelectric conversion element 21 and the TFT 22 is removed by radiation of the laser beam and the cut groove 61 is formed through the substantially entire region of the pixel 12b.

In the radiation detection apparatus according to the first variant, a moisture-resistant protection film 63 is disposed only in the cut groove 61 so as to fill the cut groove 61 in the pixel 12b. The moisture-resistant protection film 63 is not formed in the pixel 12a or a region of the pixel 12b other than the cut groove 61. Similarly to the third embodiment, the moisture-resistant protection film 63 has the metal alkoxide and the cross link of the metal alkoxide, the derivative of the metal alkoxide and the cross link of the derivative of the metal alkoxide, or the silicon dioxide (silica) and is formed with, for example, the ejecting method. With the ejecting method, the moisture-resistant protection film material can be thickly supplied only to the inside of the cut groove 61 so as to fill the cut groove 61 in a short time.

After the moisture-resistant protection film 63 has been formed, similarly to the third embodiment, for example, the scintillator layer 17 that covers the entire surface of the sensor array 12 is formed, the upper moisture-resistant protection film 18 made of Al or the like that covers the scintillator layer 17 is formed, and connection of the signal processing circuit connecting portions 13 and connection of the control circuit connecting portions 14 are performed.

According to the first variant, the surface including the metal section of the cut groove 61 formed with the repairing process is covered with the moisture-resistant protection film 63 in the pixel 12b in which a defect has occurred. Since the moisture-resistant protection film 63 is not formed in the region other than the cut groove 61, there is no concern for degradation of the MTF due to the formation of the moisture-resistant protection film 63. Since the moisture-resistant protection film 63 is formed only in the cut groove 61 which is a portion that is to be moisture resistant to a thickness with which the cut groove 61 is filled, no gap exists in the cut groove 61. Accordingly, the metal section in the surface of the cut groove 61 is reliably protected from exposure to air or water by using the thick moisture-resistant protection film 63 while a high MTF is ensured. Thus, corrosion of the metal is suppressed as much as possible, and the radiation detection apparatus of stable quality in which the pixel 12b does not exert influence on the pixel 12a around the pixel 12b is realized.

### Second Variant

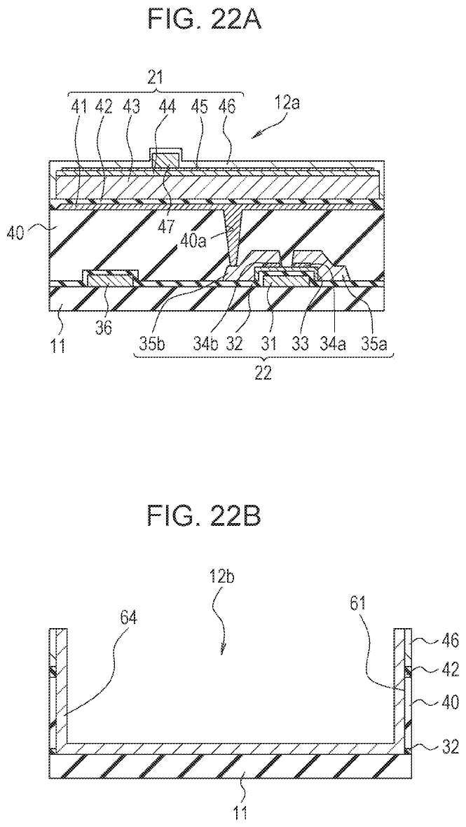

FIGS. 22A and 22B are sectional views illustrating the individual pixels in the radiation detection apparatus according to a second variant, respectively illustrating the normal pixel and the defective pixel.

According to the second variant, the normal pixel 12a is formed similarly to that illustrated in FIG. 20A of the third embodiment. Similarly to that illustrated in FIG. 20B of the third embodiment, in the pixel 12b in which a defect has occurred, the TFT 22 is removed by radiation of the laser beam and the cut groove 61 is formed.

In the radiation detection apparatus according to the second variant, a moisture-resistant protection film 64 is disposed only in the cut groove 61 so as to have a recessed shape along the surface of the cut groove 61 in the pixel 12b. Similarly to the third embodiment, the moisture-resistant protection film 64 has the metal alkoxide and the cross link of the metal alkoxide, the derivative of the metal alkoxide and the cross link of the derivative of the metal alkoxide, or the silicon dioxide (silica) and is formed to have a thickness of, for example, greater than or equal to about 0.3 nm and smaller than or equal to about 100 nm.

To form the moisture-resistant protection film 64, first, a mask that has an opening which allows only the cut groove 61 of the pixel 12b to be exposed and covers portions of the pixel 12b other than the cut groove 61 and a region on the pixels 12a is formed in the sensor array 12. The cut groove 61 is a groove formed by removing a substantially entire part of the pixel 12b, and both the widths and the area of the cut groove 61 are comparatively large. Accordingly, a mask having the opening that is aligned with the cut groove 61 so as to expose only the cut groove 61 can be easily formed. In one embodiment, the opening is exactly aligned with the cut groove 61. The film forming method similar to that of the third embodiment is executed for the insulating substrate 11 provided with this mask on the sensor array 12 to deposit the moisture-resistant protection film material on the entire surface of the mask including the surface of the cut groove 61 of the pixel 12b exposed from the opening. Then, the mask is removed.

As a result of the above-described operation, the moisture-resistant protection film 64 is formed only in the cut groove 61 so as to have a recessed shape along the surface of the cut groove 61 to a thickness of, for example, about 0.3 nm to about 100 nm similarly to the first and second embodiments.

After the moisture-resistant protection film 64 has been formed, similarly to the first and second embodiments, for example, the scintillator layer 17 that covers the entire surface of the sensor array 12 is formed, the upper moisture-resistant protection film 18 made of Al or the like that covers the scintillator layer 17 is formed, and connection of the signal processing circuit connecting portions 13 and connection of the control circuit connecting portions 14 are performed.

According to the second variant, the surface including the metal section of the cut groove 61 formed with the repairing process is covered with the moisture-resistant protection film 64 in the pixel 12b in which a defect has occurred. Since the moisture-resistant protection film 64 is not formed in the region other than the cut groove 61, there is no concern for degradation of the MTF due to the formation of the moisture-resistant protection film 64. With the moisture-resistant protection film 64, while a high MTF is ensured, the metal section of the surface of the cut groove 61 is protected from exposure to air or water, corrosion of the metal is suppressed, and the radiation detection apparatus of stable quality in which the pixel 12b does not exert influence on the pixel 12a around the pixel 12b is realized.

### Third Variant

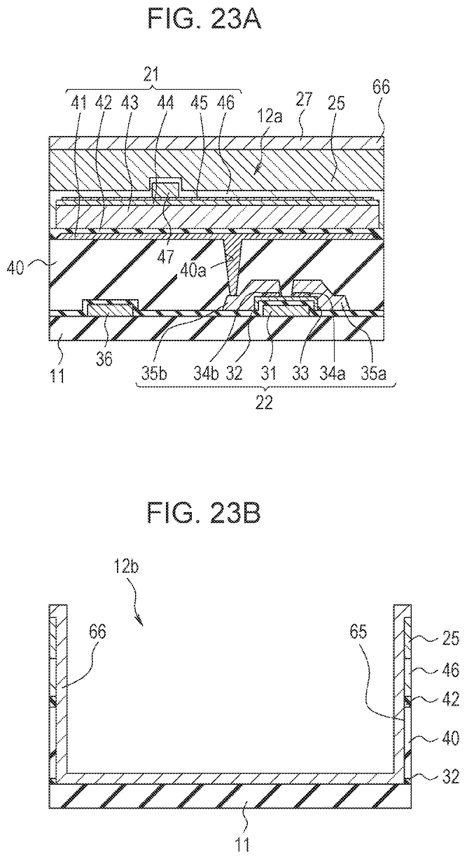

FIGS. 23A and 23B are sectional views illustrating the individual pixels in the radiation detection apparatus according to a third variant, respectively illustrating the normal pixel and the defective pixel.

In the radiation detection apparatus according to the third variant, similarly to the second variants of the first and second embodiments, the planarization layer 25 is disposed on the protecting layer 46 in the normal pixels 12a and the pixels 12b in which a defect has occurred so as to cover the pixel region 12A.

The photoelectric conversion element 21 and the TFT 22 of the pixel 12b are removed by radiation of the laser light in a state in which the planarization layer 25 has been formed. At this time, a cut groove 65 that allows part of the surface of the insulating substrate 11 to be exposed is formed in a substantially entire region of the pixel 12b. With the cut groove 65, the electrical connection of the pixel 12b to the signal processing circuit 15 and the gate driver circuit 16 is disconnected.

A moisture-resistant protection film 66 is disposed on the pixel 12a and the pixel 12b including the surface of the cut groove 65 through, for example, the entire surface of the pixel region 12A. In the cut groove 65, the moisture-resistant protection film 66 is formed so as to have a recessed shape along the surface of the cut groove 65 to a thickness of, for example, greater than or equal to about 0.3 nm and smaller than or equal to about 100 nm with the film forming method similar to that of the third embodiment.

After the moisture-resistant protection film 66 has been formed, for example, the scintillator layer 17 that covers the entire surface of the sensor array 12 is formed, the upper moisture-resistant protection film 18 made of Al or the like that covers the scintillator layer 17 is formed, and connection of the signal processing circuit connecting portions 13 and connection of the control circuit connecting portions 14 are performed. When the upper surface of the planarization layer 25 on which the scintillator layer 17 is formed is formed as a planarized surface, the occurrences of irregularities of the vapor deposition surface are suppressed, and the scintillator layer 17 exhibiting a good crystallinity for CsI or the like can be obtained.

According to the present embodiment, in the pixel 12b in which a defect has occurred, the surface including the metal section of the cut groove 65 formed by removing the TFT 22 with the repairing process is covered with the moisture-resistant protection film 66 having a small thickness. Thus, while the MTF is sufficiently ensured, the metal section of the surface of the cut groove 65 is protected from exposure to air or water, corrosion of the metal is suppressed, and the radiation detection apparatus of stable quality in which the pixel 12b does not exert influence on the pixel 12a around the pixel 12b is realized.

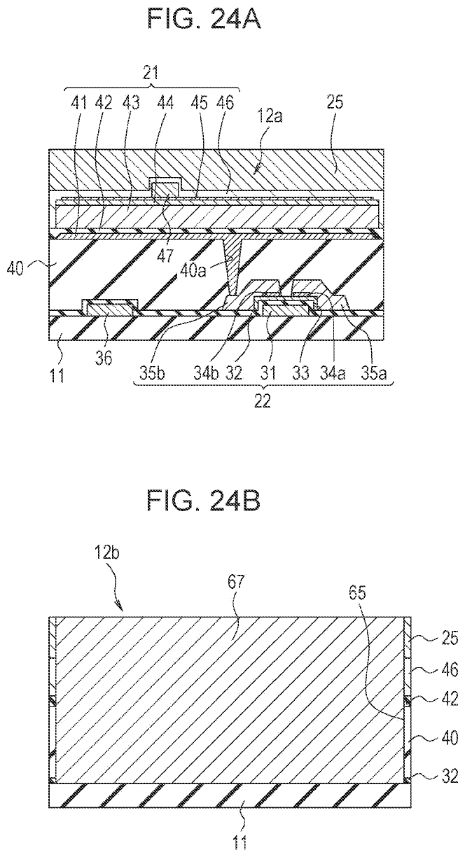

The first variant can be further applied to the third variant. FIGS. 24A and 24B are sectional views illustrating a defective pixel in the radiation detection apparatus in this case.

In the third variant, the cut groove 65 is formed with the repairing process in a state in which the planarization layer 25 has been formed, and, similarly to the above-described first variant, a moisture-resistant protection film 67 is formed so as to fill only the inside of the cut groove 65. The moisture-resistant protection film 67 is not formed in a region other than the cut groove 65. To form the moisture-resistant protection film 67, similarly to the first variant, the moisture-resistant protection film material is supplied with, for example, the ejecting method only to the cut groove 65 so as to fill the inside of the cut groove 65.

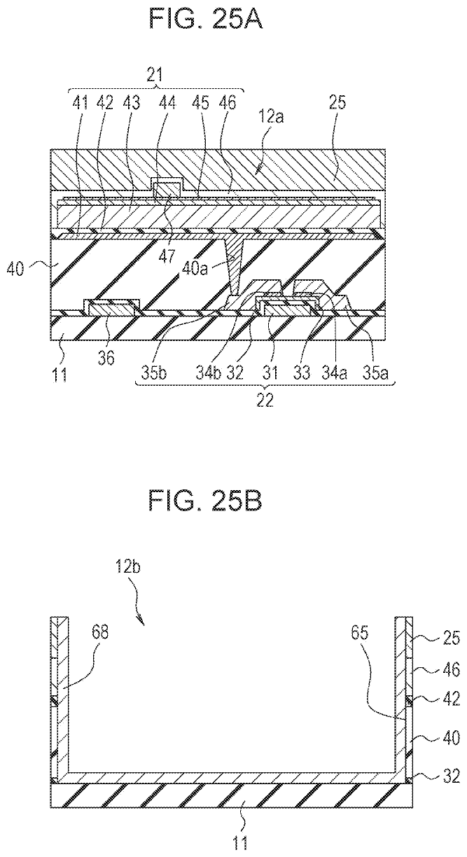

In addition, the second variant can be further applied to the third variant. FIGS. 25A and 25B are sectional views illustrating a defective pixel in the radiation detection apparatus in this case.

In the third variant, the cut groove 65 is formed with the repairing process in a state in which the planarization layer 25 has been formed, and, similarly to the above-described second variant, a moisture-resistant protection film 68 is formed only in the cut groove 65 so as to have a recessed shape along the surface of the cut groove 65 to a thickness of, for example, greater than or equal to about 0.3 nm and smaller than or equal to about 100 nm. The moisture-resistant protection film 68 is not formed in a region other than the cut groove 65. To form the moisture-resistant protection film 68, similarly to the second variant, a mask having an opening is formed on the sensor array 12, the film is formed, and the mask is removed.

### Other Embodiments

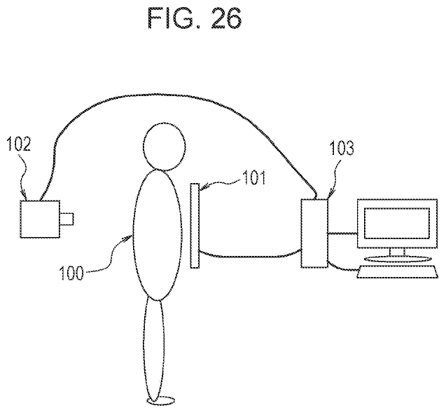

The radiation detection apparatus according to the above-described embodiments and variants can be applied to, for example, a radiation diagnostic system as illustrated in FIG. 26.

This radiation diagnostic system includes a radiation detection apparatus 101 according to one of the above-described embodiments and variants, a radiation generation apparatus 102, and a control and arithmetic processing section 103. The radiation detection apparatus 101 and the radiation generation apparatus 102 are connected to the control and arithmetic processing section 103. Under control of the control and arithmetic processing section 103, radiation is radiated from the radiation generation apparatus 102 to a subject 100. The radiation detection apparatus 101 detects the radiation transmitted through the subject 100. Information detected by the radiation detection apparatus 101 is read by the control and arithmetic processing section 103 as an electrical signal. The control and arithmetic processing section 103 performs desired arithmetic processing, and diagnosis is performed.

Any of the above-described embodiments represents only examples of embodiments in carrying out the disclosure, and the technical scope of the disclosure shall not be limitedly interpreted by these. That is, the aspect of the embodiments can be carried out in various forms without departing from the technical concepts or the main features thereof.

The disclosure of the embodiments and the variants includes the following configurations and method.

### Configuration 1

A radiation detection apparatus includes a first pixel, a second pixel, and an electrical circuit electrically connected to the first pixel.

The second pixel has a cut groove that disconnects electrical connection from the electrical circuit, and a moisture-resistant protection film that covers at least a surface of the cut groove is disposed.

### Configuration 2

In the radiation detection apparatus according to configuration 1, the moisture-resistant protection film is disposed in the cut groove so as to have a recessed shape along the surface of the cut groove.

### Configuration 3

In the radiation detection apparatus according to configuration 1, the cut groove is filled with the moisture-resistant protection film.

### Configuration 4

In the radiation detection apparatus according to configuration 2, the moisture-resistant protection film is disposed on the first pixel and the second pixel including the surface of the cut groove.

### Configuration 5

In the radiation detection apparatus according to configuration 2 or 3, the moisture-resistant protection film is formed only in the cut groove.

### Configuration 6

In the radiation detection apparatus according to any one of configurations 1 to 5, each of the first pixel and the second pixel includes a photoelectric conversion element and a switch element electrically connected to the photoelectric conversion element.

The cut groove is formed in a line electrically connected to the switch element of the second pixel.

### Configuration 7

In the radiation detection apparatus according to any one of configurations 1 to 5, each of the first pixel and the second pixel includes a conversion element.

The first pixel includes a switch element electrically connected to the conversion element.

In the second pixel, the cut groove is formed in a portion corresponding to a placement position of the switch element of the first pixel.

### Configuration 8

In the radiation detection apparatus according to any one of configurations 1 to 5, the first pixel includes a conversion element and a switch element electrically connected to the conversion element.

In the second pixel, the cut groove is formed in a portion corresponding to placement positions of the conversion element and the switch element of the first pixel.

### Configuration 9

In the radiation detection apparatus according to any one of configurations 1 to 8, the moisture-resistant protection film includes a metal alkoxide or a derivative of the metal alkoxide and a cross link formed by cross-linking, by oxygen, some of metal atoms of the metal alkoxide or some of metal atoms of the derivative of the metal alkoxide.

### Configuration 10

In the radiation detection apparatus according to configuration 9, the metal alkoxide of the moisture-resistant protection film is a chemical compound represented by a following general formula (1):

M(OR)n (1).

In formula (1) described above, M is any one selected from the group consisting of Si, Al, Ti, and Zr, R is at least one selected from the group consisting of a methyl group, an ethyl group, a propyl group, an isopropyl group, and a butyl group, and n is 4 in a case where M is Si, Ti, or Zr, and n is 3 in a case where M is Al.

### Configuration 11

In the radiation detection apparatus according to any one of configurations 1 to 8, the moisture-resistant protection film is formed by depositing silicon dioxide.

### Configuration 12

In the radiation detection apparatus according to any one of configurations 1, 2, and 4 to 11, a thickness of the moisture-resistant protection film is greater than or equal to 0.3 nm and smaller than or equal to 100 nm.

### Configuration 13

The radiation detection apparatus according to any one of configurations 1 to 12 further includes a planarization layer that has a planarized surface and that is disposed above the first pixel and the second pixel.

The cut groove is formed in a portion of the second pixel including the planarization layer.

### Configuration 14

The radiation detection apparatus according to any one of configurations 1 to 13 further includes a scintillator layer disposed above the first pixel and the second pixel and an upper moisture-resistant protection film disposed on the scintillator layer.

### Method 1

A method for manufacturing a radiation detection apparatus includes the step of forming a plurality of pixels electrically connected to an electrical circuit.

The method also includes the step of identifying a pixel in which a defect has occurred out of the plurality of pixels.

The method also includes the step of forming, in the pixel in which a defect has occurred, a cut groove that disconnects electrical connection to the electrical circuit.

The method also includes the step of forming a moisture-resistant protection film that covers at least a surface of the cut groove.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-184870 filed Nov. 18, 2022, which is hereby incorporated by reference herein in its entirety.

What is claimed is:

1. A panel in which a plurality of pixels and a circuit are connected to each other,
wherein, in the panel, a cutting process with which connection between a defective pixel out of the plurality of pixels and the circuit is disconnected is performed,
wherein a protection film is formed in a cut groove of the cutting process, and
wherein the protection film is formed by exposing the panel having undergone the cutting process to a gas of a protection material, and the protection film has a thickness of greater than or equal to 0.3 nm and smaller than or equal to 100 nm.

2. The panel according to claim 1, wherein the protection film is formed to have a recessed shape along the cut groove.

3. The panel according to claim 1, wherein the protection film is formed only in the cut groove.

4. The panel according to claim 1,
wherein each of the plurality of pixels includes a conversion element and a switch element connected to the conversion element, and
wherein a line on which the cutting process has been performed is connected to the switch element of the defective pixel.

5. The panel according to claim 1,
wherein each of the plurality of pixels includes a conversion element and a switch element connected to the conversion element, and
wherein a region of the defective pixel corresponding to the switch element is cut out with the cutting process.

6. The panel according to claim 1,
wherein each of the plurality of pixels includes a conversion element and a switch element connected to the conversion element, and
wherein a region of the defective pixel corresponding to the conversion element is cut out with the cutting process.

7. The panel according to claim 1, wherein the protection material includes one of a metal alkoxide or a derivative of the metal alkoxide and a cross link formed by cross-linking, by oxygen, some of metal atoms of the metal alkoxide or some of metal atoms of the derivative of the metal alkoxide.

8. The panel according to claim 7, wherein the metal alkoxide is a chemical compound represented by a following general formula (1),
M(OR)n (1),
where M is any one selected from the group consisting of Si, Al, Ti, and Zr,
R is at least one selected from the group consisting of a methyl group, an ethyl group, a propyl group, an isopropyl group, and a butyl group, and
n is 4 in a case where M is Si, Ti, or Zr, and n is 3 in a case where M is Al.

9. The panel according to claim 1, wherein the protection film is formed by depositing silicon dioxide.

10. The panel according to claim 1,
wherein a planarization layer having a planarized surface is further provided as a layer overlying the plurality of pixels, and
wherein a partial region of the planarization layer positioned above the defective pixel is cut out with the cutting process.

11. The panel according to claim 1,
wherein a scintillator layer is provided as a layer overlying the plurality of pixels, and
wherein the protection film is formed as a layer further overlying the scintillator layer.

12. The panel according to claim 1, wherein the gas of the protection material is used in any of a spattering method, a chemical-vapor deposition method, a plasma chemical-vapor deposition method, and evacuation.

13. The panel according to claim 4, wherein the conversion element is a photoelectric conversion element.

14. A method for manufacturing a panel in which a plurality of pixels and a circuit are connected to each other, the method comprising:
disconnecting a line connecting a pixel in which a defect has occurred out of the plurality of pixels and the circuit from each other; and
forming a protection film in a cut groove of the line by exposing, to a gas of a protection material, the panel in which the line has been disconnected,
wherein a thickness of the protection film is greater than or equal to 0.3 nm and smaller than or equal to 100 nm.

15. The method according to claim 14, wherein the protection film is formed (i) to have a recessed shape along the cut groove or (ii) in the cut groove.

16. The method according to claim 14, wherein the protection material includes one of a metal alkoxide or a derivative of the metal alkoxide and a cross link formed by cross-linking, by oxygen, some of metal atoms of the metal alkoxide or some of metal atoms of the derivative of the metal alkoxide.

17. The method according to claim 16, wherein the metal alkoxide is a chemical compound represented by a following general formula (1),
M(OR)n (1),
where M is any one selected from the group consisting of Si, Al, Ti, and Zr,
R is at least one selected from the group consisting of a methyl group, an ethyl group, a propyl group, an isopropyl group, and a butyl group, and
n is 4 in a case where M is Si, Ti, or Zr, and n is 3 in a case where M is Al.

18. A panel in which a plurality of pixels and a circuit are connected to each other,
wherein, in the panel, a cutting process with which connection between a defective pixel out of the plurality of pixels and the circuit is disconnected is performed,
wherein a protection film is formed in a cut groove of the cutting process, and
wherein the protection film includes, as a material, one of a metal alkoxide or a derivative of the metal alkoxide and a cross link formed by cross-linking, by oxygen, some of metal atoms of the metal alkoxide or some of metal atoms of the derivative of the metal alkoxide.

19. The panel according to claim 18, wherein the protection film is formed (1) to have a recessed shape along the cut groove or (2) in the cut groove.

20. The panel according to claim 18, wherein the metal alkoxide is a chemical compound represented by a following general formula (1),
M(OR)n (1),
where M is any one selected from the group consisting of Si, Al, Ti, and Zr,
R is at least one selected from the group consisting of a methyl group, an ethyl group, a propyl group, an isopropyl group, and a butyl group, and
n is 4 in a case where M is Si, Ti, or Zr, and n is 3 in a case where M is Al.
